(19) United States
(12) Patent Application Publication
(10) Pub. No.: US 2024/0322034 A1
(43) Pub. Date: Sep. 26, 2024

(54) SEMICONDUCTOR DEVICE AND MANUFACTURING METHOD THEREOF

(71) Applicant: ROHM CO., LTD., Kyoto-shi (JP)

(72) Inventor: Keita AOYAMA, Kyoto-shi (JP)

(73) Assignee: ROHM CO., LTD., Kyoto-shi (JP)

(21) Appl. No.: 18/607,746

(22) Filed: Mar. 18, 2024

(30) Foreign Application Priority Data
Mar. 20, 2023 (JP) 2023-044154

(51) Int. Cl. H01L 29/78; H01L 29/40; H01L 29/51; H01L 29/66

(52) U.S. Cl. CPC H01L 29/7813; H01L 29/407; H01L 29/513; H01L 29/66734

(57) ABSTRACT

The semiconductor device 10 includes: a gate trench; a field plate electrode and a gate electrode formed in the gate trench; and an insulating layer separating the field plate electrode and the gate electrode from each other. The semiconductor layer includes an n-type drift region and a p-type body region formed on the drift region. The insulating layer 16 includes a first insulating layer covering the field plate electrode and a second insulating layer formed on the first insulating layer at a position adjacent to the drift region. The second insulating layer has a dielectric constant greater than that of the first insulating layer. The second insulating layer is disposed between a bottom surface of the field plate electrode and a bottom surface of the gate electrode along a Z direction.

### TECHNICAL FIELD

The present disclosure relates to a semiconductor device and a manufacturing method thereof.

### BACKGROUND

Patent document 1 discloses a metal insulator semiconductor field effect transistor (MISFET) having a split-gate structure. The split-gate structure includes a gate trench formed on a semiconductor layer, an embedded electrode embedded in a bottom portion of the gate trench and serving as a field plate electrode, and a gate electrode embedded in an upper portion of the gate trench. The gate electrode and the field plate electrode are separated by an insulating layer in the gate trench.

### PRIOR ART DOCUMENT

### [Patent Publication]

[Patent document 1] Japan Patent Publication No. 2018-129378

### BRIEF DESCRIPTION OF THE DRAWINGS

FIG. 1 is a plan view of a semiconductor device according to an embodiment.

FIG. 2 is a schematic cross-sectional view of a semiconductor device along a section line F2-F2 in FIG. 1.

FIG. 3 is an enlarged schematic cross-sectional view of one gate trench and its periphery in the semiconductor device in FIG. 2.

FIG. 4 is an enlarged schematic cross-sectional view of a second insulating layer and its periphery in the semiconductor device in FIG. 3.

FIG. 5 is a schematic cross-sectional view of a semiconductor device along a section line F5-F5 in FIG. 1.

FIG. 6 is schematic cross-sectional view of a manufacturing step of a semiconductor device according to an embodiment.

FIG. 7 is a schematic cross-sectional view of a manufacturing step after FIG. 6.

FIG. 8 is a schematic cross-sectional view of a manufacturing step after FIG. 7.

FIG. 9 is a schematic cross-sectional view of a manufacturing step after FIG. 8.

FIG. 10 is a schematic cross-sectional view of a manufacturing step after FIG. 9.

FIG. 11 is a schematic cross-sectional view of a manufacturing step after FIG. 10.

FIG. 12 is a schematic cross-sectional view of a manufacturing step after FIG. 11.

FIG. 13 is a schematic cross-sectional view of a manufacturing step after FIG. 12.

FIG. 14 is a schematic cross-sectional view of a manufacturing step after FIG. 13.

FIG. 15 is a schematic cross-sectional view of a manufacturing step after FIG. 14.

FIG. 16 is a schematic cross-sectional view of a manufacturing step after FIG. 15.

FIG. 17 is a schematic cross-sectional view of a manufacturing step after FIG. 16.

FIG. 18 is a schematic cross-sectional view of a manufacturing step after FIG. 17.

FIG. 19 is a schematic cross-sectional view of a manufacturing step after FIG. 18.

FIG. 20 is a schematic cross-sectional view of a manufacturing step after FIG. 19.

FIG. 21 is an enlarged schematic cross-sectional view of one gate trench and its periphery in a semiconductor device of a comparison example.

FIG. 22 is an enlarged schematic cross-sectional view of one gate trench and its periphery in a semiconductor device according to an embodiment.

FIG. 23 is an enlarged schematic cross-sectional view of one gate trench and its periphery in a semiconductor device of a variation example.

### DETAILED DESCRIPTION OF THE EMBODIMENTS

Details of several embodiments of a semiconductor device of the present disclosure are provided with the accompanying drawings below. To keep the description clear and simple, the constituting elements shown in the accompanying drawings are not necessarily drawn to fixed scales. Moreover, for better understanding, shading lines may be omitted from the sectional views. It should be noted that the drawings are for illustrating the embodiments of the present disclosure, and are not to be construed as limitations to the present disclosure.

The description below includes details for implementing a device, a system and a method of the exemplary embodiments of the present disclosure. The detailed description is only intended for illustration purposes and is not to be construed as limitations to the embodiments of the present disclosure or applicability or uses of the embodiments.

### [Planar Structure of Semiconductor Device)

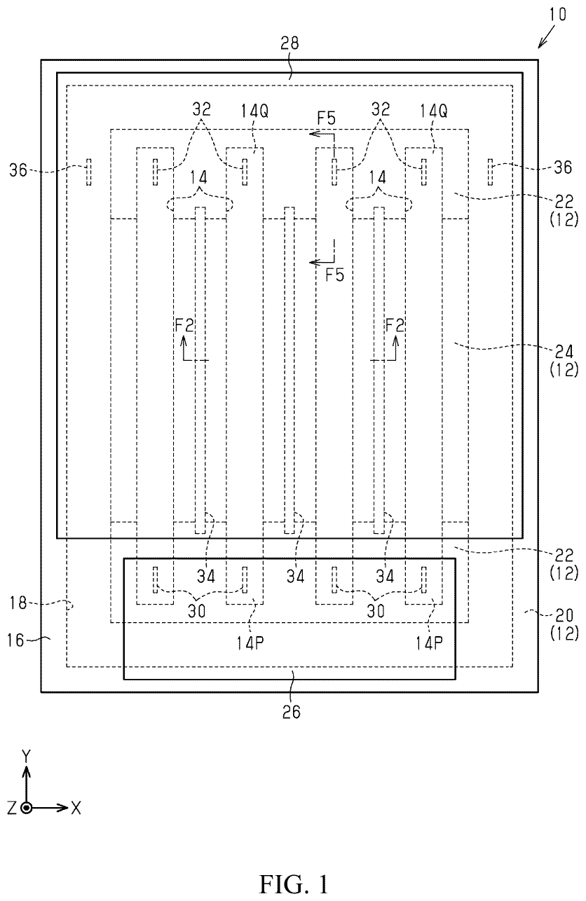

Referring to FIG. 1, the planar structure of a semiconductor device according to an embodiment is described below.

FIG. 1 shows a brief planar structure of an illustrative semiconductor device 10 according to an embodiment. Moreover, the expression “in a plan view” used in the present disclosure refers to observing the semiconductor device 10 in a Z-direction with X-axis, Y-axis and Z-axis being orthogonal to one another, as shown in FIG. 1. Unless otherwise specified, the term “plan view’ refers to observing the semiconductor device 10 from the top along the Z-axis.

The semiconductor device 10 is, for example, a metal insulator semiconductor field effect transistor (MISFET) having a split-gate structure. The semiconductor device 10 includes a semiconductor layer 12, a gate trench 14 formed on the semiconductor layer 12, and an insulating layer 16 formed on the semiconductor layer 12. Moreover, in the present application, the gate trench 14 is an example of “a trench”.

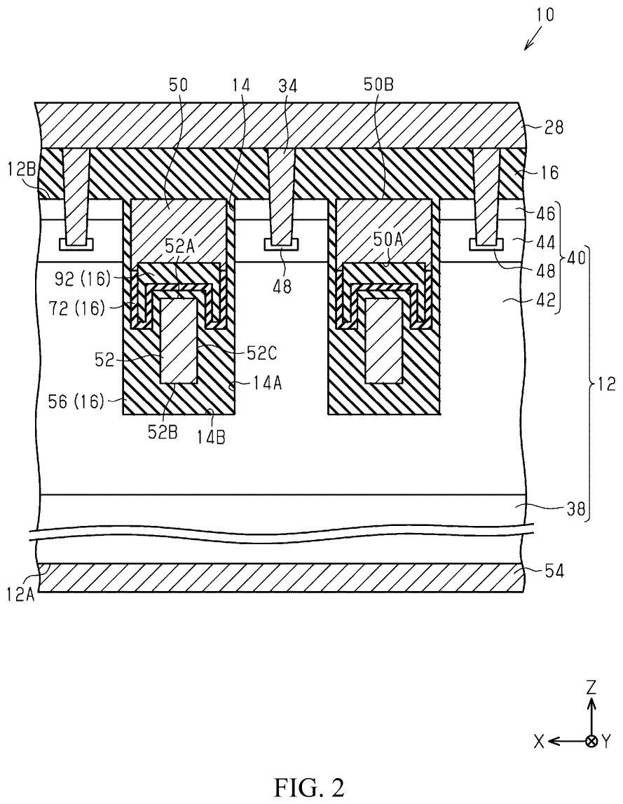

The semiconductor layer 12 can be formed of silicon (Si). The semiconductor layer 12 has a first surface 12A and a second surface 12B on a side opposite to the first surface 12A (referring to FIG. 2 for both of the above), and has a thickness in a direction (the Z direction) perpendicular to the first surface 12A. That is to say, the Z direction can be said as “a thickness direction of the semiconductor layer 12”.

The gate trench 14 has an opening on the second surface 12B of the semiconductor layer 12, and has a depth in the Z direction. Thus, the gate trench 14 can also be said as being formed on the second surface 12B. Moreover, the gate trench 14 extends along the Y direction in the plan view, and has a width along the X direction. In the present application, the Z direction is also referred to as “a depth direction of the gate trench 14”, the Y direction is referred to as “a first direction”, and the X direction is referred to as “a second direction”. Thus, the depth direction of the gate trench 14 is orthogonal to both of the first direction and the second direction, and the second direction is orthogonal to the first direction in the plan view.

The semiconductor device 10 includes a plurality of (four in the example in FIG. 1) gate trenches 14. The plurality of gate trenches 14 can also be arranged neatly in strips. In an example, the plurality of gate trenches 14 can be arranged equidistantly along the X direction in the plan view. A gate electrode 50 and a field plate electrode 52 to be described shortly with reference to FIG. 2 can be disposed in the gate trench 14. Each of the gate trenches 14 has a first end 14P and a second end 14Q as two ends along the Y direction.

The semiconductor device 10 can further include a peripheral trench 18 formed on the semiconductor layer 12. The peripheral trench 18 can be formed to be separated from the gate trenches 14 and to surround the plurality of gate trenches 14 in the plan view. In an example, the peripheral trench 18 is formed to have a rectangular shape with the X direction as a short-side direction and the Y direction as a long-side direction. A peripheral electrode (omitted from the drawing) formed in accordance with the shape of the peripheral trench 18 can be disposed in the peripheral trench 18.

As shown in FIG. 1, the second surface 12B of the semiconductor layer 12 can include an n⁻-type region 20 containing n-type impurities, a p⁻-type region 22 containing p-type impurities, and an n⁺-type region 24 containing n-type impurities. The n⁻-type region 20 can also surround the peripheral trench 18. Moreover, the p⁻-type region 22 and the n⁺-type region 24 can be surrounded by the peripheral trench 18. That is to say, the n⁻-type region 20, the p⁻-type region 22 and the n⁺-type region 24 are defined by the peripheral trench 18.

The p⁻-type region 22 and the n⁺-type region 24 are arranged along the Y direction. Moreover, the p⁻-type region 22 can be provided as plural in number (two in the example shown in FIG. 1). Two p⁻-type regions 22 are dispersed on both sides of the n⁺-type region 24 along the Y direction. In other words, the n⁺-type region 24 can be located between the two p⁻-type regions 22 along the Y direction. Moreover, since a pn junction interface between the p⁻-type region 22 and the n⁺-type region 24 is not exposed due to the presence of the peripheral trench 18, a withstand voltage of the semiconductor device 10 can be increased.

Each of the gate trenches 14 can be disposed to be adjacent to both of the p⁻-type region 22 and the n⁺-type region 24. The first end 14P of the gate trench 14 can be adjacent to one of the two p⁻-type regions 22, and the second end 14Q of the gate trench 14 can be adjacent to the remaining one of the two p⁻-type regions 22. On the other hand, a middle portion of the gate trench 14 can be adjacent to the n⁺-type region 24.

The insulating layer 16 covers the second surface 12B of the semiconductor layer 12, and is embedded in the gate trench 14 and the peripheral trench 18. The insulating layer 16 is a layer that insulates the gate electrode 50 and the field plate electrode 52 from the semiconductor layer 12.

The semiconductor device 10 can further include a gate wiring 26 and a source wiring 28 formed on the insulating layer 16. Each of the gate wiring 26 and the source wiring 28 can be disposed to cover a portion of the gate trench 14 and a portion of the peripheral trench 18. The gate wiring 26 can be disposed to at least partially overlap one of the two p⁻-type regions 22. The source wiring 28 can be disposed to at least partially overlap the other of the two p⁻-type regions 22. The source wiring 28 can be separated from the gate wiring 26 and at least covers an entirety of the n⁺-type region 24.

The gate wiring 26 and the source wiring 28 can be formed of a material including at least one of titanium (Ti), nickel (Ni), gold (Au), silver (Ag), copper (Cu), aluminum (Al), Cu alloy and Al alloy.

The semiconductor device 10 can further include a plurality of gate contacts 30. Each of the gate contacts 30 can connect the gate electrode 50 (referring to FIG. 2) disposed in each of the gate trenches 14 to the gate wiring 26. The gate contact 30 extends along the Z direction to be able to pass through the insulating layer 16 located between the gate electrode 50 and the gate wring 26. The gate contact 30 can be disposed in a region in which the gate trench 14 overlaps the gate wiring 26 in the plan view. More specifically, the gate contact 30 can be disposed in a region in which the first end 14P of the gate trench 14 overlaps the gate wiring 26 in the plan view

The semiconductor device 10 can further include a plurality of source contacts 32. Each of the source contacts 32 can connect the field plate electrode 52 disposed in each of the gate trenches 14 to the source wiring 28. The source contact 32 extends along the Z direction to be able to pass through the insulating layer 16 located between the field plate electrode 52 and the gate wring 28. The source contact 32 can be disposed in a region in which the gate trench 14 overlaps the source wiring 28 in the plan view. More specifically, the source contact 32 can be disposed in a region in which the second end 14Q of the gate trench 14 overlaps the source wiring 28 in the plan view.

The semiconductor device 10 can further include one or a plurality of wiring contacts 34 extending along the Y direction in the plan view. The wiring contact 34 can at least extend from one end to the other end of the n⁺-type region 24 along the Y direction in the plan view. The wiring contact 34 can be disposed between two adjacent gate trenches 14. The wiring contact 34 can connect a contact region 48 (referring to FIG. 2) formed in the semiconductor layer 12 to the source wiring 28. The wiring contact 34 extends along the Z direction to be able to pass through the semiconductor layer 12 and the insulating layer 16 located between the contact region 48 and the source wiring 28.

The semiconductor device 10 can further include one or a plurality of contacts 36 that connect the peripheral electrode (omitted from the drawing) disposed in the peripheral trench 18 to the source wiring 28. The number and configuration position of the contact 36 are not limited to the examples shown in FIG. 1, and can be modified as desired.

The gate contact 30, the source contact 32, the wiring contact 34, and the contact 36 can be formed of any metal material as desired. In an example, each of the contacts 30, 32, 34 and 36 can be formed of a material including at least one of tungsten (W), Ti and titanium nitride (TiN).

### [Cross-Section Structure of Semiconductor Device)

Referring to FIG. 2 to FIG. 5, the cross-section structure of the semiconductor device 10 is described below.

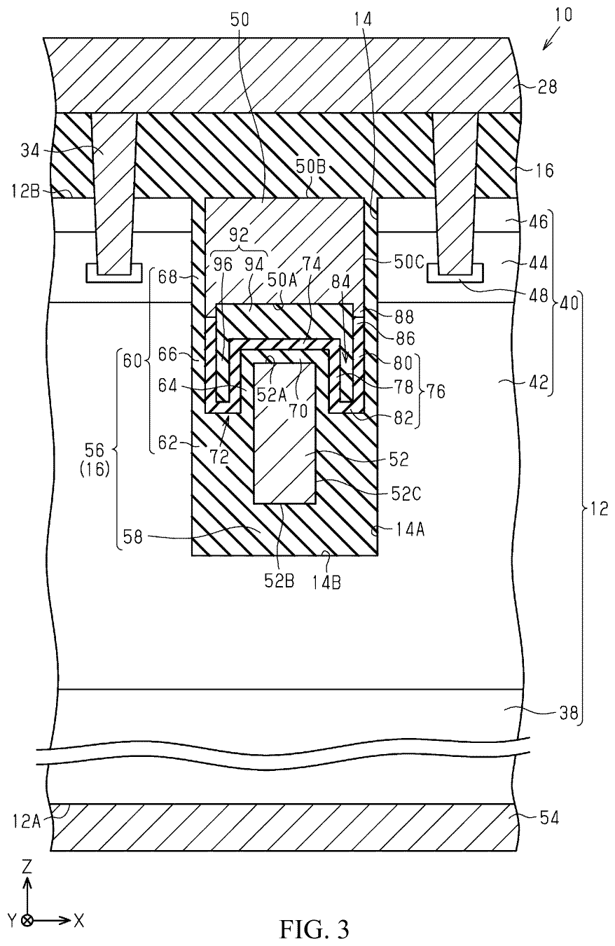

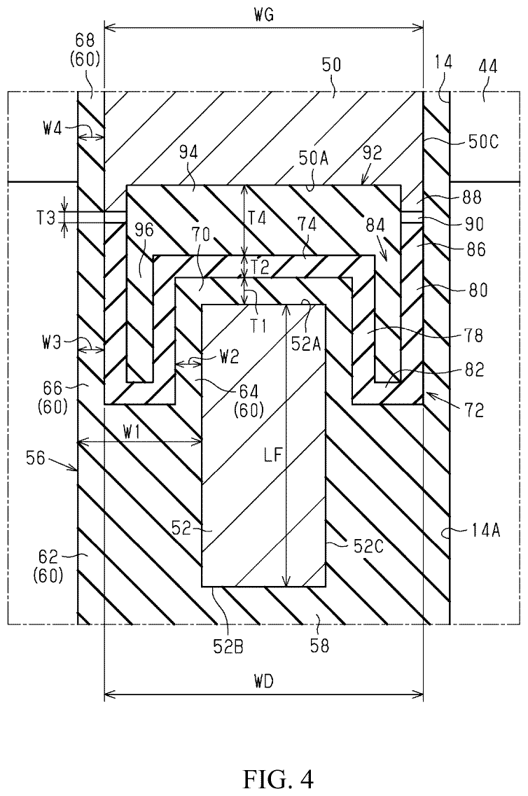

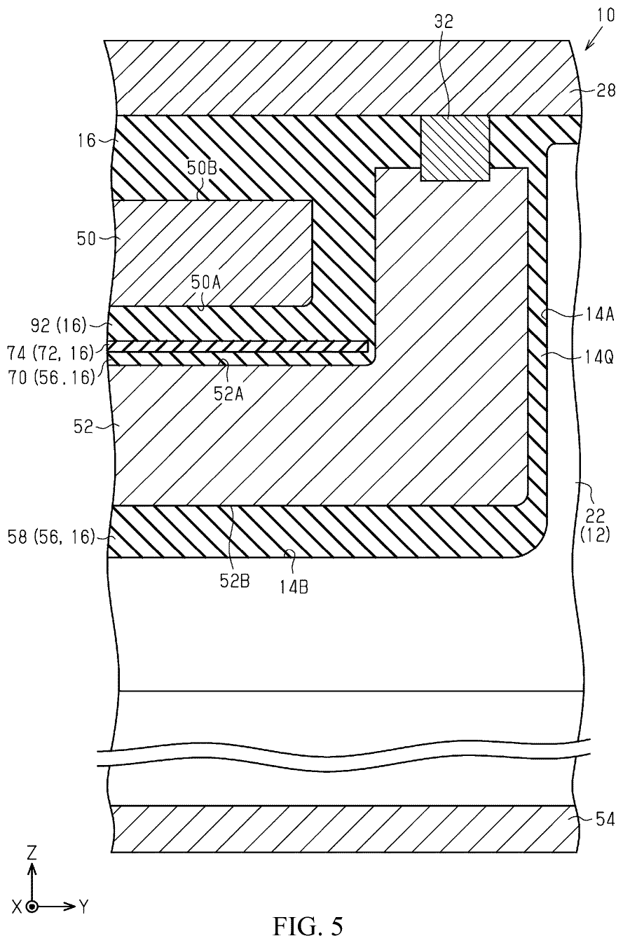

FIG. 2 shows a brief cross-section structure of the semiconductor device 10 along a section line F2-F2 in FIG. 1. FIG. 3 shows an enlarged brief cross-section structure of one gate trench 14 and its periphery in FIG. 2. FIG. 4 shows an enlarged brief cross-section structure of a second insulating layer 72 to be described shortly and its periphery in FIG. 3. FIG. 5 shows a brief cross-section structure of the semiconductor device 10 along a section line F5-F5 in FIG. 1.

The semiconductor layer 12 can include: a semiconductor substrate 38, including the first surface 12A of the semiconductor layer 12; and an epitaxial layer 40, formed on the semiconductor substrate 38, including the second surface 12B of the semiconductor layer 12. The semiconductor substrate 38 can be formed of a material including Si. In an example, the semiconductor substrate 38 can be a Si substrate. The semiconductor substrate 38 can correspond to a drain region of the MISFET. Thus, the semiconductor substrate 38 is also referred to as “a drain region 38” in some cases. The epitaxial layer 40 can be a Si layer epitaxially grown on the Si substrate. The epitaxial layer 40 can include a drift region 42, a body region 44 formed on the drift region 42, and a source region 46 formed on the body region 44. The source region 46 can include the second surface 12B of the semiconductor layer 12. An upper surface (the second surface 12B) of the source region 46 corresponds to the n⁺-type region 24 in FIG. 1. The epitaxial layer 40 can further include a contact region 48 located below the wiring contact 34.

The drain region 38 (the semiconductor substrate 38) can be an n⁺-type region containing n-type impurities. An n-type impurity concentration of the drain region 38 can be set to between about 1×1018 cm⁻³ and about 1×10²⁰ cm⁻³. The drain region 38 can have a thickness of, for example, between about 50 μm and about 450 μm.

The drift region 42 can be an n⁻-type region having an n-type impurity concentration less than that of the drain region 38. The n-type impurity concentration of the drift region 42 can be set to between about 1×10¹⁵ cm⁻³ and about 1×10¹⁸ cm⁻³. The drift region 42 can have a thickness of, for example, between about 1 μm and about 25 μm.

The body region 44 can be a p⁻-type region containing p-type impurities. A p-type impurity concentration of the body region 44 can be set to between about 1×10¹⁶ cm⁻³ and about 1×10¹⁸ cm⁻³. The body region 44 can have a thickness of, for example, between about 0.5 μm and about 1.5 μm.

The source region 46 can be an n*-type region having an n-type impurity concentration greater than that of the drift region 42. The n-type impurity concentration of the source region 46 can be set to between about 1×10¹⁹ cm⁻³ and about 1×10²¹ cm⁻³. The source region 46 can have a thickness of, for example, between about 0.1 μm and about 1 μm.

The contact region 48 can be a p⁺-type region containing p-type impurities. The contact region 48 is connected to the body region 44. More specifically, the contact region 48 is formed between two adjacent gate trenches 14 along the X direction in the body region 44. A p-type impurity concentration of the contact region 48 is greater than that of the body region 44, and can be set to, for example, between about 1×10¹⁹ cm⁻³ and about 1×10²¹ cm⁻³.

In addition, in the present disclosure, the n type is also referred to as a first conductivity type, and the p type is also referred to as a second conductivity type. The n-type impurities can be, for example, phosphorus (P) and arsenic (As). Moreover, the p-type impurities can be, for example, boron (B) and aluminum (Al).

The gate trench 14 has a side wall 14A and a bottom wall 14B, wherein the bottom wall 14B is adjacent to the drift region 42. That is to say, the gate trench 14 passes through the source region 46 and the body region 44 of the semiconductor layer 12 and reaches the drift region 42. A depth of the gate trench 14 can be, for example, between about 1 μm and about 10 μm. The depth of the gate trench 14 can be defined as a distance from the second surface 12B of the semiconductor layer 12 to the bottom wall 14B (a deepest portion of the gate trench 14 when the bottom wall 14B is curved) of the gate trench 14 along the Z direction. Moreover, the Z direction corresponds to “a depth direction of the gate trench 14 (trench)”.

The side wall 14A of the gate trench 14 can extend along a direction (the Z direction) perpendicular to the second surface 12B of the semiconductor layer 12. Moreover, the side wall 14A can also, for example, be inclined with respect to the Z direction to have a width of the gate trench 14 decrease toward the bottom wall 14B. Moreover, the bottom wall 14B of the gate trench 14 is not necessarily flat, and can be, for example, partially or entirely curved.

The semiconductor device 10 can further include: a gate electrode 50 disposed in the gate trench 14; and a field plate electrode 52 disposed in the gate trench 14 and separated below from the gate electrode 50 along the Z direction. The field plate electrode 52 includes an opposing surface 52A facing the gate electrode 50 across from the insulating layer 16, a bottom surface 52B facing the bottom wall 14B of the gate trench 14 across from the insulating layer 16, and a side surface 52C connected to the opposing surface 52A and the bottom surface 52B. The opposing surface 52A of the field plate electrode 52 is at a position closer to the bottom wall 14B of the gate trench 14 than the gate electrode 50 along the Z direction.

The gate electrode 50 can include a bottom surface 50A at least partially facing the opposing surface 52A of the field plate electrode 52, and an upper surface 50B on a side opposite to the bottom surface 50A. At least a portion of the bottom surface 50A of the gate electrode 50 can face the opposing surface 52A of the field plate electrode 52 along the Z direction. The upper surface 50B of the gate electrode 50 can be located at, for example, a position the same as the second surface 12B of the semiconductor layer 12 along the Z direction. In other examples, the upper surface 50B of the gate electrode 50 can be located at, for example, a position closer to the bottom wall 14B of the gate trench 14 than the second surface 12B of the semiconductor layer 12. Both of the bottom surface 50A and the upper surface 50B of the gate electrode 50 can be flat or can be curved. As shown in FIG. 2, the gate electrode 50 can have a substantially same width (a dimension along the X direction). In another example, the gate electrode 50 can have a width that decreases as getting away from the upper surface 50B toward the bottom surface 50A.

The insulating layer 16 can be interposed between the gate electrode 50 and the semiconductor layer 12, and cover the side wall 14A of the gate trench 14. The gate electrode 50 faces the semiconductor layer 12 across from the insulating layer 16 along the X direction. If a predetermined voltage is applied to the gate electrode 50, a channel is formed in the p⁻-type body region 44 adjacent to the insulating layer 16. The semiconductor device 10 can control flow of electrons between the n⁺-type source region 46 ad the n⁻-type drift region 42 along the Z direction through the channel.

The gate electrode 50 can be located at, for example, a position at which its bottom surface 50A is not closer to the bottom wall 14B of the gate trench 14 than an interface between the drift region 42 and the body region 44 along the Z direction. In an example, the gate electrode 50 can be disposed to have its bottom surface 50A be located at a same position as the interface between the drift region 42 and the body region 44 along the Z direction. In another example, the gate electrode 50 can also be disposed to have its bottom surface 50A be located at a position closer to the second surface 12B of the semiconductor layer 12 than the interface between the drift region 42 and the body region 44.

The field plate electrode 52 is disposed between the bottom surface 50A of the gate electrode 50 and the bottom wall 14B of the gate trench 14 in the gate trench 14. The field plate electrode 52 can be set to have a same potential as the source region 46. By applying a source voltage to the field plate electrode 52, electric field concentration in the gate trench 14 can be alleviated, hence increasing withstand voltage of the semiconductor device 10. In the sectional view of FIG. 2, the field plate electrode 52 is formed to have a rectangular shape with the Z direction as a lengthwise direction (a long-side direction) and the X direction as a widthwise direction (a short-side direction). The gate electrode 50 and the field plate electrode 52 are formed of, for example, conductive polysilicon.

The semiconductor device 10 can further include a drain electrode 54 formed on the first surface 12A of the semiconductor layer 12. The drain electrode 54 is electrically connected to the drain region 38. The drain electrode 54 can be formed of a material including at least one of Ti, Ni, Au, Ag, Cu, Al, Cu alloy and Al alloy

In the cross section in FIG. 2, a source wiring 28 is formed on the insulating layer 16. The source wiring 28 covers the insulating layer 16, and is electrically connected to the contact region 48 via the wiring contact 34

### [Cross-Section Structure of Insulating Layer]

With reference to FIG. 3 and FIG. 4, the insulating layer 16 covering the field plate electrode 52 and the gate electrode 50 is further described in detail below. Dimension relationship of the individual constituting elements can be primarily referred to FIG. 4.

As shown in FIG. 3, the insulating layer 16 can include a first insulating layer 56 covering the side wall 14A and the bottom wall 14B of the gate trench 14, and covering the field plate electrode 52. The first insulating layer 56 is formed of, for example, a material including SiO₂. In an example, the first insulating layer 56 is formed by a SiO₂ film.

The first insulating layer 56 can include a bottom insulating portion 58 and a side insulating portion 60. The bottom insulating layer 58 is interposed between the bottom surface 52B of the field plate electrode 52 and the Z direction of the semiconductor layer 12, and covers the bottom wall 14B of the gate trench 14. The side insulating portion 60 is interposed between the side surface 52C of the field plate electrode 52 and the X direction of semiconductor layer 12, and covers the side surface 52C of the field plate electrode 52. In an example, the bottom insulating portion 58 and the side insulating portion 60 can be formed integrally.

The side insulating portion 60 can include a first side insulating portion 62, a first interposing portion 64, a second interposing portion 66 and a second side insulating portion 68. In an example, the first side insulating portion 62, the first interposing portion 64, the second interposing portion 66 and the second side insulating portion 68 can be formed integrally.

The first side insulating portion 62 is an insulating portion formed close to the bottom insulating portion 58 in the side insulating portion 60. The first side insulating portion 62 is interposed between the side surface 52C of the field plate electrode 52 and the X direction of semiconductor layer 12, and covers the side wall 14A of the gate trench 14.

The first interposing portion 64 is an insulating portion formed to be closer to the gate electrode 50 than the first side insulating portion 62 in the side insulating portion 60. The first interposing portion 64 is interposed between the side surface 52C of the field plate electrode 52 and the X direction of semiconductor layer 12, and is formed at a position separated from the side wall 14A of the gate trench 14 along the X direction. The first interposing portion 64 is in contact with the side surface 52C of the field plate electrode 52. Thus, a width W2 (a dimension along the X direction) of the first interposing portion 64 is less than a width W1 (a dimension along the X direction) of the first side insulating portion 62.

The second interposing portion 66 is an insulating portion formed to be closer to the gate electrode 50 than the first side insulating portion 62 in the side insulating portion 60. The second interposing portion 66 includes a portion at a same position as the first interposing portion 64 along the Z direction. On the other hand, the second interposing portion 66 extends further toward the second surface 12B than the first interposing portion 64 along the Z direction. The second interposing portion 66 is formed to be separated from the field plate electrode 52 along the X direction. Thus, a width W3 (a dimension along the X direction) of the second interposing portion 66 is less than the width W1 of the first side insulating portion 62. In an example, the width W3 of the second interposing portion 66 is equal to the width W2 of the first interposing portion 64. Herein, if a difference between the width W3 of the second interposing portion 66 and the width W2 of the first interposing portion 64 is, for example, within 10% of the width W3 of the second interposing portion 66, it can be said that the width W3 of the second interposing portion 66 is equal to the width W2 of the first interposing portion 64.

The second side insulating portion 68 is connected to the insulating layer 16 covering the second surface 12B of the semiconductor layer 12. The second side insulating portion 68 covers the side wall 14A of the gate trench 14. In an example, the second side insulating portion 68 is connected to both of the side surface 50C of the gate electrode 50 and the semiconductor layer 12 forming the side wall 14A of the gate trench 14. The second side insulating portion 68 is continuous with the second interposing portion 66. A width W4 (a dimension along the X direction) of the second side insulating portion 68 can be, for example, equal to the width W3 (the dimension along the X direction) of the second interposing portion 66.

The first insulating layer 56 can further include an opposing insulating portion 70 covering the opposing surface 52A of the field plate electrode 52. The opposing insulating portion 70 can be in contact throughout an entirety of the opposing surface 52A. The opposing insulating portion 70 extends from the first interposing portion 64 toward a direction orthogonal to the Z direction. That is to say, the opposing insulating portion 70 extends along the X direction in the sectional view of FIG. 3. The opposing insulating portion 70 extends along the Y direction in the sectional view of FIG. 5. As shown in FIG. 3, in an example, a thickness T1 of the opposing insulating portion 70 is, for example, equal to the width W2 of the first interposing portion 64. Herein, if a difference between the thickness T1 of the opposing insulating portion 70 and the width W2 of the first interposing portion 64 is, for example, within 10% of the width W2 of the first interposing portion 64, it can be said that the thickness T1 of the opposing insulating portion 70 is equal to the width W2 of the first interposing portion 64.

The insulating layer 16 can further include a second insulating layer 72 formed in the first insulating layer 56 and at a position adjacent to the drift region 42. The second insulating layer 72 is disposed between the bottom surface 52B of the field plate electrode 52 and the bottom surface 50A of the gate electrode 50 along the Z direction. Thus, the second insulating layer 72 is not disposed on a portion closer to the second surface 12B of the semiconductor layer 12 than the bottom surface 50A of the gate electrode 50. That is to say, the second insulating layer 72 is not interposed between the gate electrode 50 and the X direction of the side wall 14A of the gate trench 14. In an example, only the first insulating layer 56 is interposed between the gate electrode 50 and the X direction of the side wall 14A of the gate trench 14.

A dielectric constant of the second insulating layer 72 is greater than a dielectric constant of the first insulating layer 56. The second insulating layer 72 can be formed of, for example, a material including at least one of silicon nitride (SiN), silicon oxynitride (SiON), and hafnium dioxide (HfO₂). In an example, the second insulating layer 72 can be formed by a SiN film. The dielectric constant of the second insulating layer 72 is adjusted to be greater than the dielectric constant of the first insulating layer 56 based on, for example, a composition ratio of Si and N. Moreover, the second insulating layer 72 can be formed by a SiON film or can be formed by a HfO₂ film.

The second insulating layer 72 can include an opposing portion 74 and a side opposing portion 76. In this embodiment, the opposing portion 74 and the side opposing portion 76 can be formed integrally.

The opposing portion 74 is disposed between the gate electrode 50 and the field plate electrode 52 in a depth direction (the Z direction) of the gate trench 14. The opposing portion 74 is formed on the opposing insulating portion 70 of the first insulating layer 56. The opposing insulating portion 70 can be said as including a portion sandwiched between the opposing portion 74 and the opposing surface 52A of the field plate electrode 52 along the Z direction.

In the sectional view of FIG. 3, the opposing portion 74 can extend along the X direction. That is to say, in the sectional view of FIG. 3, the opposing portion 74 can be said as extending along the width direction of the gate trench 14. In the sectional view of FIG. 5, the opposing portion 74 can extend along the Y direction. In an example, the opposing portion 74 extends closer to the second end 14Q of the gate trench 14 than the gate electrode 50.

The side opposing portion 76 includes a portion disposed opposite to the side surface 52C of the field plate electrode 52. The side opposing portion 76 includes a first side opposing portion 78, a second side opposing portion 80 and a connection portion 82. In an example, the first side opposing portion 78, the second side opposing portion 80 and the connection portion 82 can be formed integrally.

The first side opposing portion 78 extends from the opposing portion 74 to the bottom wall 14B of the gate trench 14. The first side opposing portion 78 can extend, for example, along the side wall 14A of the gate trench 14. Thus, the first side opposing portion 78 can be said as extending in parallel to the side wall 14A. The first side opposing portion 78 is disposed between the side surface 52C of the field plate electrode 52 and the side wall 14A of the gate trench 14 along the X direction. The first side opposing portion 78 is disposed to be separated from both of the side surface 52C of the field plate electrode 52 and the side wall 14A of the gate trench 14 along the X direction. The first side opposing portion 78 is in contact with the first insulating layer 56. More specifically, the first side opposing portion 78 is in contact with the first interposing portion 64, by being disposed closer to the side wall 14A of the gate trench 14 with respect to the first interposing portion 64. Thus, the first interposing portion 64 can be also said as being sandwiched between the first side opposing portion 78 and the side surface 52C of the field plate electrode 52 along the X direction.

The second side opposing portion 80 is disposed opposite to the first side opposing portion 78, by being disposed to be close to the side wall 14A of the gate trench 14 and separated from the first side opposing portion 78. The second side opposing portion 80 can extend, for example, along the side wall 14A of the gate trench 14. Thus, the second side opposing portion 80 can be said as extending in parallel to the side wall 14A. In addition, the second side opposing portion 80 can also be said as extending in parallel to the first side opposing portion 78. The second side opposing portion 80 is disposed to be separated from the side wall 14A of the gate trench 14 along the X direction. The second side opposing portion 80 is in contact with the first insulating layer 56. More specifically, the second side opposing portion 80 is in contact with the second interposing portion 66, by being disposed close to the field plate electrode 52 with respect to the second interposing portion 66. The second side opposing portion 80 can also be said as disposed between the first side opposing portion 78 and the X direction of the second interposing portion 66.

The connection portion 82 can connect an end of the first side opposing portion 78 close to the bottom wall 14B of the gate trench 14 with the second side opposing portion 80. In the example shown in FIG. 3, the connection portion 82 is connected to an end of the second side opposing portion 80 close to the bottom wall 14B of the gate trench 14. The connection portion 82 can be disposed at a position closer to the gate electrode 50 than the center of the field plate electrode 52 along the Z direction. That is to say, both of the first side opposing portion 78 and the second side opposing portion 80 can be said as covering a portion of the side surface 52C of the field plate electrode 52 closer to the gate electrode 50 than the center along the Z direction. In an example, the connection portion 82 can be disposed at a position approximately ⅓ of a length dimension LF (a dimension along the Z direction) of the field plate electrode 52 from the opposing surface 52A of the field plate electrode 52 along the Z direction. Thus, the side opposing portion 76 forms a recess 84 open to the gate electrode 50 through the first side opposing portion 78, the second side opposing portion 80 and the connection portion 82.

The second insulating layer 72 can further include a protruding portion 86. The protruding portion 86 is formed continuously from the second side opposing portion 80 and protrudes from the opposing portion 74 toward the gate electrode 50. The protruding portion 86 can be formed integrally with the second side opposing portion 80. The protruding portion 86 can extend along the side wall 14A of the gate trench 14. Thus, the protruding portion 86 can be said as extending in parallel to the side wall 14A. The protruding portion 86 is disposed opposite to the gate electrode 50 along the Z direction.

A portion of the gate electrode 50 facing the protruding portion 86 along the Z direction can include a gate-side protrusion 88 protruding from the bottom surface 50A of the gate electrode 50 toward the protruding portion 86. The gate-side protrusion 88 can be formed integrally with the gate electrode 50. The gate-side protrusion 88 is disposed on two ends of the gate electrode 50 along the X direction. The gate-side protrusion 88 protrudes further toward the drift region 42 than a border between the body region 44 and the drift region 42 along the Z direction.

As shown in FIG. 4, an oxide film 90 is interposed between the protruding portion 86 along the Z direction and the gate-side protrusion 88. The oxide film 90 can be formed of, for example, a material including silicon (SiO). In an example, the oxide film 90 is a SiO₂ film. A thickness T3 of the oxide film 90 is, for example, less than a thickness T2 of the second insulating layer 72.

A maximum dimension WD of the second insulating layer 72 along the X direction can be less than a maximum dimension WG of the gate electrode 50 along the X direction. In an example, the maximum dimension WD of the second insulating layer 72 along the X direction can be equal to the maximum dimension WG of the gate electrode 50 along the X direction.

As shown in FIG. 3, the insulating layer 16 can include a third insulating layer 92 formed between the second insulating layer 72 and the gate electrode 50 along the Z direction. A dielectric constant of the third insulating layer 92 is less than a dielectric constant of the second insulating layer 72. In an example, the dielectric constant of the third insulating layer 92 is equal to the dielectric constant of the first insulating layer 56. The third insulating layer 92 can be formed of, for example, a material including SiO. In an example, the third insulating layer 92 is a SiO₂ film.

The third insulating layer 92 is disposed at a portion surrounded by the second insulating layer 72, the gate electrode 50 and the oxide film 90 (referring to FIG. 4). The third insulating layer 92 can include a dielectric portion 94 disposed on the opposing portion 74 of the second insulating layer 72, and an embedded portion 96 entering the recess 84 of the second insulating layer 72. The dielectric portion 94 and the embedded portion 96 can be formed integrally.

The dielectric portion 94 is a portion sandwiched between the bottom surface 50A of the gate electrode 50 and the opposing portion 74 of the second insulating layer 72 in the third insulating layer 92. A thickness T4 of the dielectric portion 94 can be greater than the thickness T1 of the opposing insulating portion 70 of the first insulating layer 56. In an example, the thickness T4 of the dielectric portion 94 is greater than or equal to twice the thickness T1 of the opposing insulating portion 70. In an example, the thickness T4 of the dielectric portion 94 is smaller than or equal to five times the thickness T1 of the opposing insulating portion 70.

The embedded portion 96 can extend along the side wall 14A of the gate trench 14 in the sectional view of FIG. 3. The embedded portion 96 is disposed between the first side opposing portion 78 of the second insulating layer 72 and the X direction of the second side opposing portion 80. Thus, between the side surface 52C of a portion of the field plate electrode 52 closer to the opposing surface 52A than the center along the Z direction and the X direction of the side wall 14A of the gate trench 14, from the side surface 52C toward the side wall 14A, the first interposing portion 64 of the first insulating layer 56, the first side opposing portion 78 of the second insulating layer 72, the embedded portion 96 of the third insulating layer 92, the second side opposing portion 80 of the second insulating layer 72 and the second interposing portion 66 of the first insulating layer 56 are sequentially disposed.

### [Manufacturing Method of Semiconductor Device]

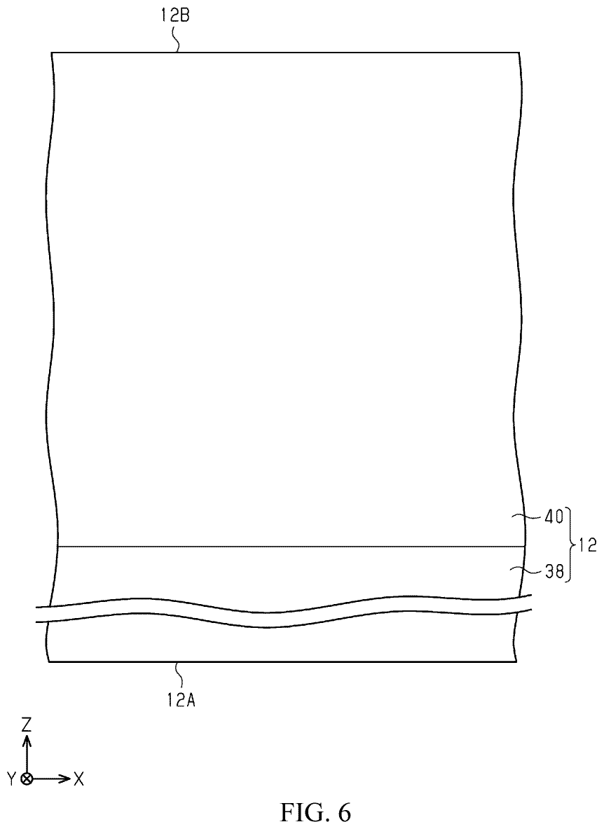

Referring to FIG. 6 to FIG. 20, an example of a manufacturing method of the semiconductor device 10 is described below. FIG. 6 to FIG. 20 show schematic cross-sectional views of exemplary manufacturing steps of the semiconductor device 10. Moreover, for better understanding, in FIG. 6 to FIG. 20, the constituting elements the same as the constituting elements in FIG. 2 to FIG. 4 are denoted by the same numerals or symbols.

As shown in FIG. 6, the manufacturing method of the semiconductor device 10 includes forming the epitaxial layer 40 on the semiconductor substrate 38. Accordingly, the semiconductor layer 12 including the semiconductor substrate 38 and the epitaxial layer 40 is formed. The semiconductor substrate 38 can be a Si substrate including n-type impurities. The epitaxial layer 40 can be an n⁻-type Si layer epitaxially grown on the semiconductor substrate 38 while n-type impurities are doped.

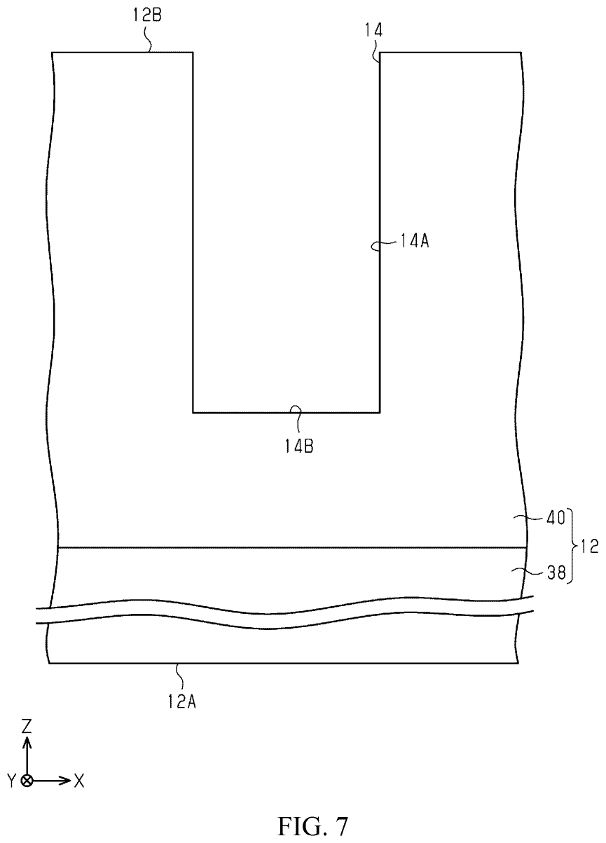

As shown in FIG. 7, the manufacturing method of the semiconductor device 10 further includes forming the gate trench 14 having the side wall 14A and the bottom wall 14B on the semiconductor layer 12. In the step above, a portion of the epitaxial layer 40 is selectively removed by etching using a mask (omitted from the drawing) formed of a predetermined pattern formed on the second surface 12B of the semiconductor layer 12. Accordingly, the gate trench 14 having an opening can be formed on the second surface 12B of the semiconductor layer 12. The gate trench 14 extends along the Y direction in the plan view. Herein, the Y direction corresponds to “a first direction”. Moreover, the Z direction corresponds to “a depth direction of the gate trench 14 (trench)”.

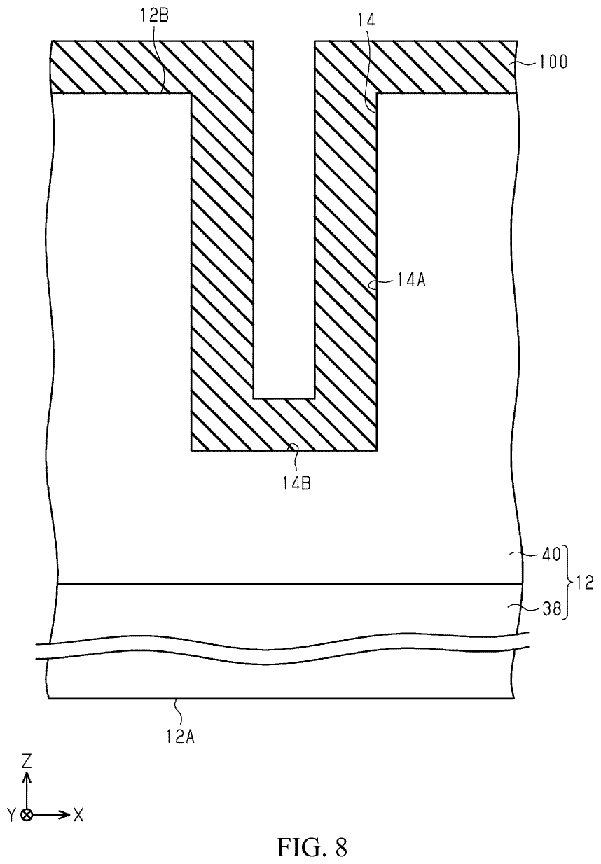

As shown in FIG. 8, the manufacturing method of the semiconductor device 10 includes forming a first SiO-based insulating layer 100 on the semiconductor layer 12. The first SiO-based insulating layer 100 can be formed along the second surface 12B of the semiconductor layer 12, and the side wall 14A and the bottom wall 14B of the gate trench 14. In an example, the first SiO-based insulating layer 100 can be SiO₂ formed by thermal oxidation. In another example, the first SiO-based insulating layer 100 can also be SiO₂ formed by chemical vapor deposition (CVD). Thus, the first SiO-based insulating layer 100 can be a SiO₂ film.

By adjusting the thickness of the first SiO-based insulating layer 100 in the step above, a dimension (for example, a dimension along the X direction) of the bottom surface 52B (referring to FIG. 3) of the field plate electrode 52 finally formed can be adjusted. The first SiO-based insulating layer 100 is not formed thick enough to completely fill the gate trench 14. A recess space formed in the gate trench 14 that is not embedded by the first SiO-based insulating layer 100 can be used to form the field plate electrode 52 in a subsequent step.

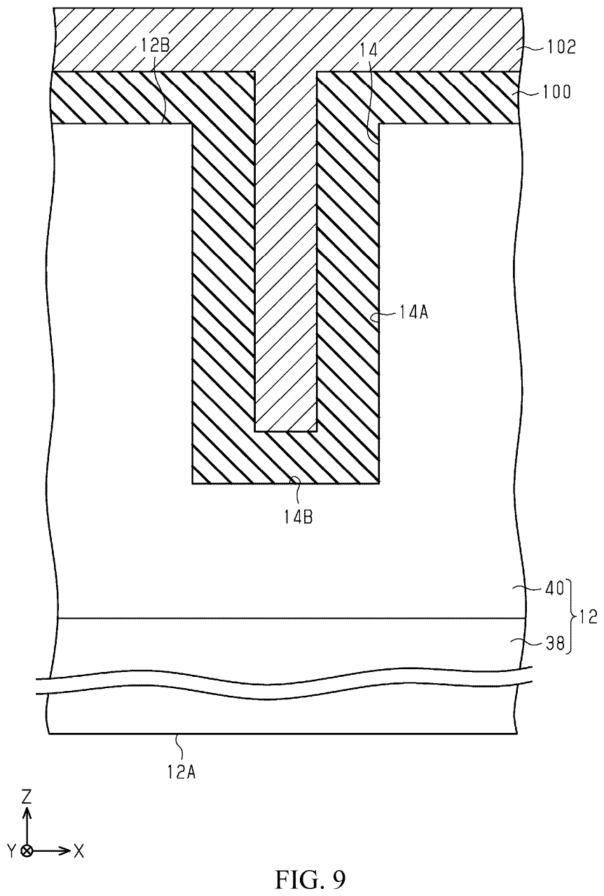

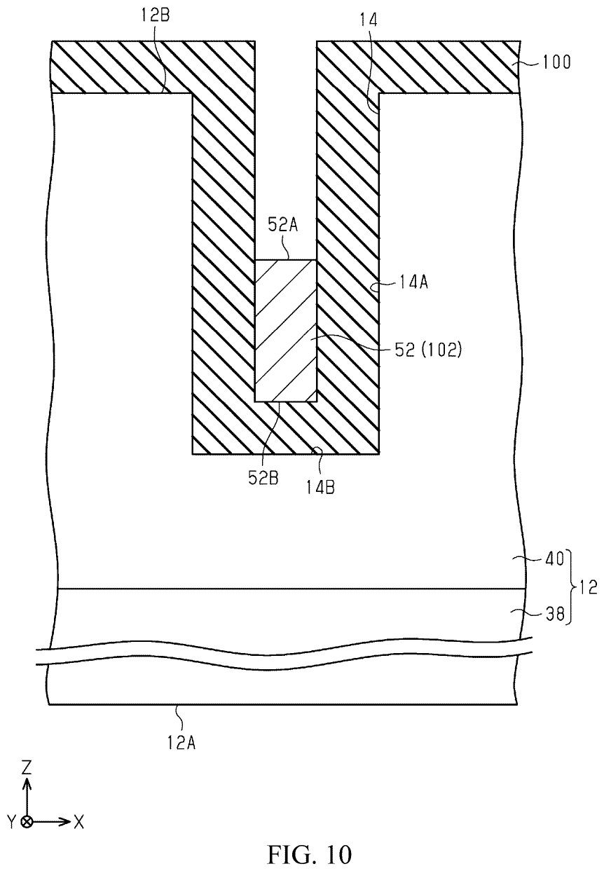

As shown in FIG. 9 and FIG. 10, the manufacturing method of the semiconductor device 10 includes forming the field plate electrode 52 (referring to FIG. 10) in the gate trench 14. As shown in FIG. 9, the forming of the field plate electrode 52 in the gate trench 14 includes forming a first conductive layer 102 on the first SiO-based insulating layer 100. A portion of the first conductive layer 102 is embedded in the recess space formed in the gate trench 14. Accordingly, the first SiO-based insulating layer 100 and the first conductive layer 102 can be embedded in the gate trench 14. The first conductive layer 102 is, for example, conductive polysilicon. The first conductive layer 102 can be formed by, for example, sputtering.

As shown in FIG. 10, the forming of the field plate electrode 52 in the gate trench 14 includes removing a portion of the first conductive layer 102 by etching. In the step above, by etching the first conductive layer 102, the first SiO-based insulating layer 100 covering the second surface 12B of the semiconductor layer 12 can be exposed. On the other hand, an upper surface of the first conductive layer 102 in the gate trench 14 is located at midway of a depth direction (the Z direction) of the gate trench 14. With the steps above, the field plate electrode 52 is formed.

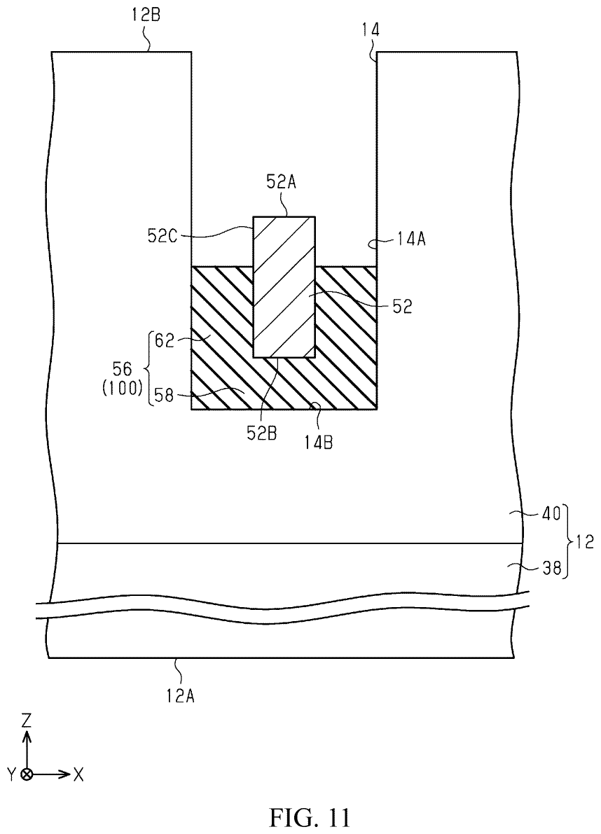

As shown in FIG. 11, the manufacturing method of the semiconductor device 10 includes removing a portion of the first SiO-based insulating layer 100 by etching. In the step above, the following portions can be etched, that is, with respect to a portion in the first SiO-based insulating layer 100 closer to the opposing surface 52A than a center of the field plate electrode 52 along the Z direction in the gate trench 14, a portion formed closer to the second surface 12B of the semiconductor layer 12, and a portion formed on the second surface 12B of the semiconductor layer 12. As a result, the side surface 52C and the opposing surface 52A of the portion closer to the opposing surface 52A than the center of the field plate electrode 52 along the Z direction can be exposed. Moreover, a portion of the side wall 14A of the gate trench 14 and the second surface 12B of the semiconductor layer 12 can be exposed. Moreover, the bottom insulating portion 58 and the first side insulating portion 62 of the first insulating layer 56 can be formed from the first SiO-based insulating layer 100.

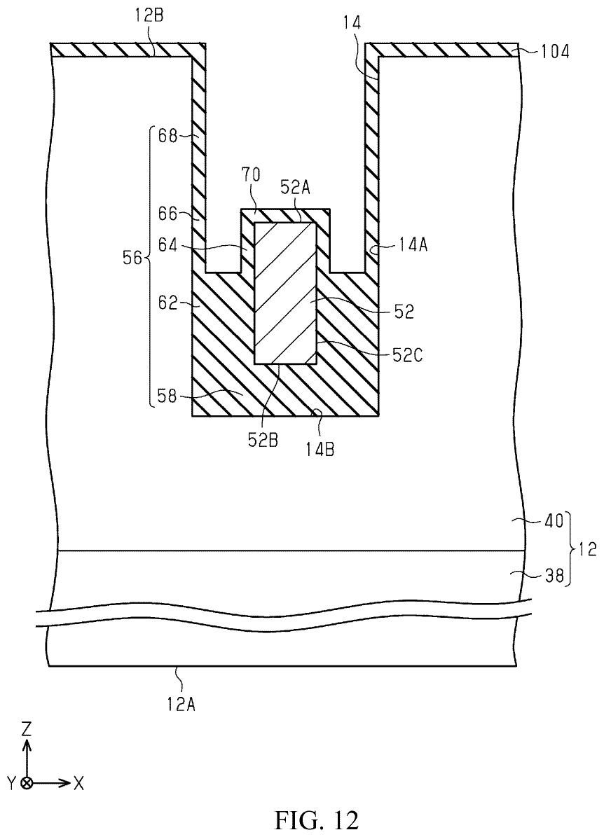

As shown in FIG. 12, the manufacturing method of the semiconductor device 10 includes forming a second SiO-based insulating layer 104 on the semiconductor layer 12. The second SiO-based insulating layer 104 can be formed along a portion exposed from the field plate electrode 52, a portion exposed from the side wall 14A of the gate trench 14, and the second surface 12B of the semiconductor layer 12. In an example, the second SiO-based insulating layer 104 can be SiO₂ formed by thermal oxidation. In another example, the second SiO-based insulating layer 104 can be SiO₂ formed by CVD. Thus, the second SiO-based insulating layer 104 can be a SiO₂ film. The second SiO-based insulating layer 104 can be formed to have a smaller thickness. In an example, the second SiO-based insulating layer 104 can be formed to have a thickness less than that of the first SiO-based insulating layer 100.

In the step above, with the second SiO-based insulating layer 104, the first interposing portion 64, the second interposing portion 66, the second side insulating portion 68 and the opposing insulating portion 70 of first insulating layer 56 can be formed. That is to say, the first insulating layer 56 is formed by the steps of forming the SiO-based insulating layers in FIG. 8, FIG. 9 and FIG. 12. Thus, the manufacturing method of the semiconductor device 10 includes forming the first insulating layer 56 covering the side wall 14A and the bottom wall 14B of the gate trench 14 and covering the field plate electrode 52.

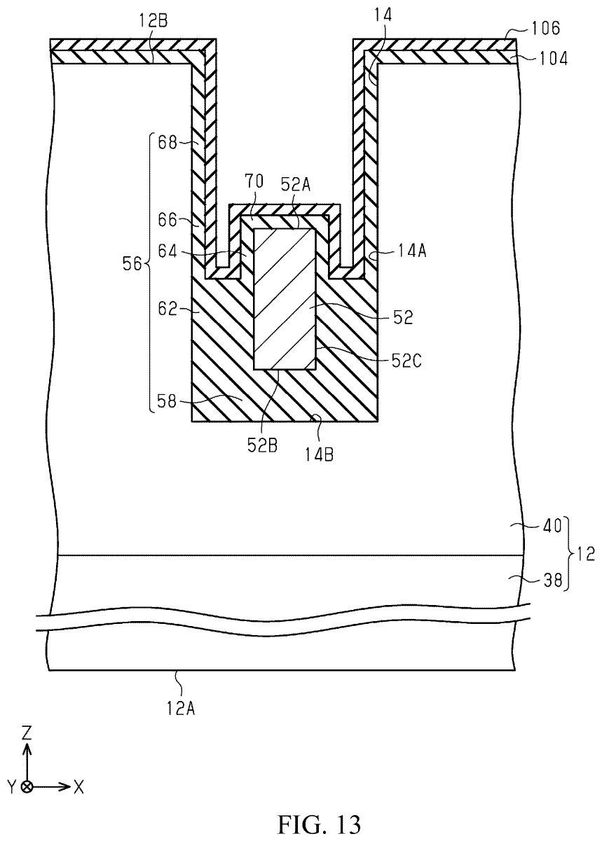

As shown in FIG. 13, the manufacturing method of the semiconductor device 10 includes forming a SiN-based insulating layer 106 on the second SiO-based insulating layer 104. The SiN-based insulating layer 106 can be formed on the second SiO-based insulating layer 104 formed on the second surface 12B of the semiconductor layer 12, the second SiO-based insulating layer 104 forming the first interposing portion 64 and the opposing insulating portion 70, and the second SiO-based insulating layer 104 forming the second interposing portion 66 and the second side insulating portion 68. In an example, the SiN-based insulating layer 106 can be SiN formed by low-pressure (LP) CVD. That is to say, the SiN-based insulating layer 106 can be a SiN film. A dielectric constant of the SiN-based insulating layer 106 can be increased in comparison with that of the first insulating layer 56 by adjusting a composition ratio of Si and N. Moreover, the SiN-based insulating layer 106 can be formed to have a smaller thickness. In an example, the SiN-based insulating layer 106 can be formed to have a thickness less than that of the first SiO-based insulating layer 100 (referring to FIG. 10). In another example, the SiN-based insulating layer 106 can be formed to have a thickness equal to that of the second SiO-based insulating layer 104. In another example, the SiN-based insulating layer 106 can be formed to have a thickness greater than that of the second SiO-based insulating layer 104. In another example, the SiN-based insulating layer 106 can be formed to have a thickness less than that of the second SiO-based insulating layer 104. Thus, the thickness of the SiN-based insulating layer 106 can be modified as desired.

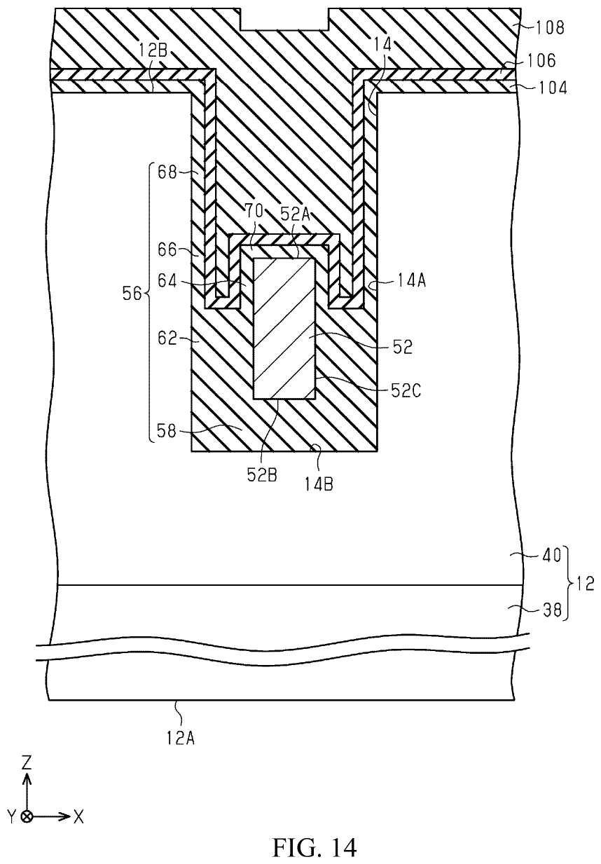

As shown in FIG. 14, the manufacturing method of the semiconductor device 10 includes forming a third SiO-based insulating layer 108 on the SiN-based insulating layer 106. The third SiO-based insulating layer 108 can be embedded in the recess space in the gate trench 14. The third SiO-based insulating layer 108 can be formed on the SiN-based insulating layer 106 formed on the second surface 12B of the semiconductor layer 12. In an example, the third SiO-based insulating layer 108 can be SiO₂ formed by CVD. More specifically, the third SiO-based insulating layer 108 can be SiO₂ formed in combination with CVD, that is, high-density plasma (HDP) and LP CVD. Thus, the third SiO-based insulating layer 108 can be a SiO₂ film. Thus, a dielectric constant of the third SiO-based insulating layer 108 is less than the dielectric constant of the SiN-based insulating layer 106.

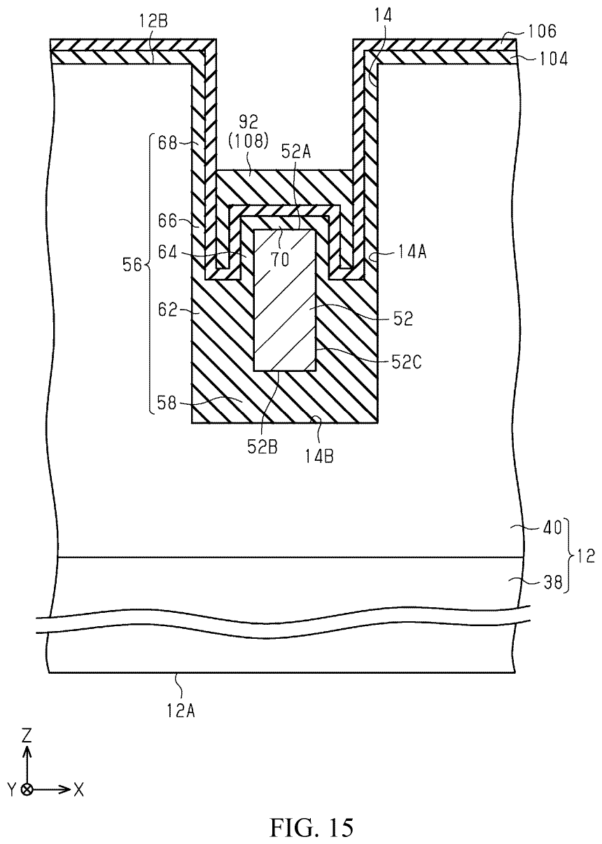

As shown in FIG. 15, the manufacturing method of the semiconductor device 10 includes removing a portion of the third SiO-based insulating layer 108 by etching. In the step above, by etching a portion of the third SiO-based insulating layer 108, the SiN-based insulating layer 106 formed on the side wall 14A of the gate trench 14 and the SiN-based insulating layer 106 formed on the second surface 12B of the semiconductor layer 12 can be exposed. On the other hand, an upper surface of the third SiO-based insulating layer 108 in the gate trench 14 is located at midway of the depth direction (the Z direction) of the gate trench 14. The upper surface of the third SiO-based insulating layer 108 is polished by, for example, chemical mechanical polishing (CMP). As a result, the upper surface of the third SiO-based insulating layer 108 can be formed as a flat surface orthogonal to the Z direction. With the steps above, the third insulating layer 92 is formed on a portion of the SiN-based insulating layer 106. Herein, the upper surface of the third SiO-based insulating layer 108 is a side facing the same side as the second surface 12B of the semiconductor layer 12 in the third SiO-based insulating layer 108.

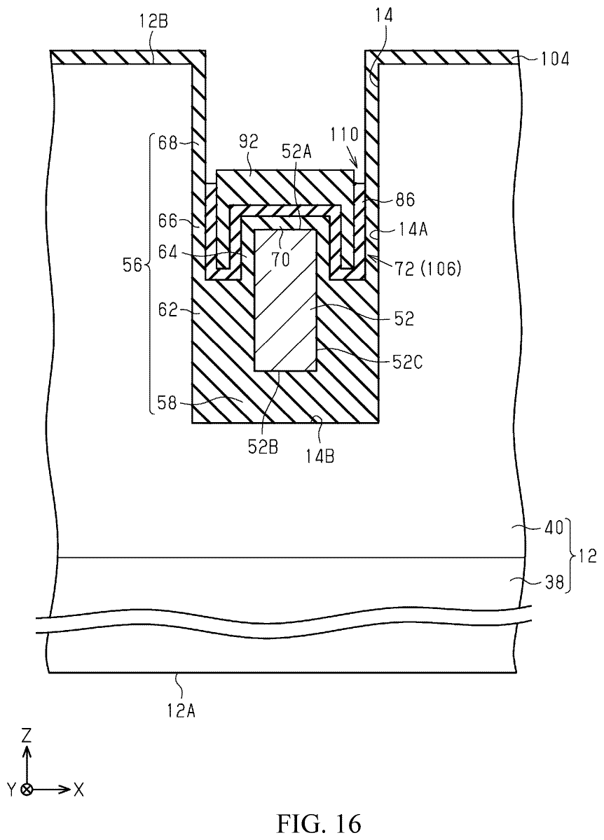

As shown in FIG. 16, the manufacturing method of the semiconductor device 10 includes removing a portion of the SiN-based insulating layer 106 by etching. The etching is performed by, for example, wet etching. In the step above, by etching a portion of the SiN-based insulating layer 106, the second SiO-based insulating layer 104 formed on the side wall 14A of the gate trench 14, and the second SiO-based insulating layer 104 formed on the second surface 12B of the semiconductor layer 12 can be exposed.

By performing the steps shown in FIG. 13 and FIG. 16, a second insulating layer 72 is formed from the SiN-based insulating layer 106. As shown in FIG. 16, a front end surface of the protruding portion 86 of the second insulating layer 72 is located at a position closer to the field plate electrode 52 than an upper surface (the upper surface of the third SiO-based insulating layer 108) of the third insulating layer 92. That is to say, a recess 110 is formed by the third insulating layer 92, the protruding portion 86 of the second insulating layer 72 and the second side insulating portion 68 of the first insulating layer 56.

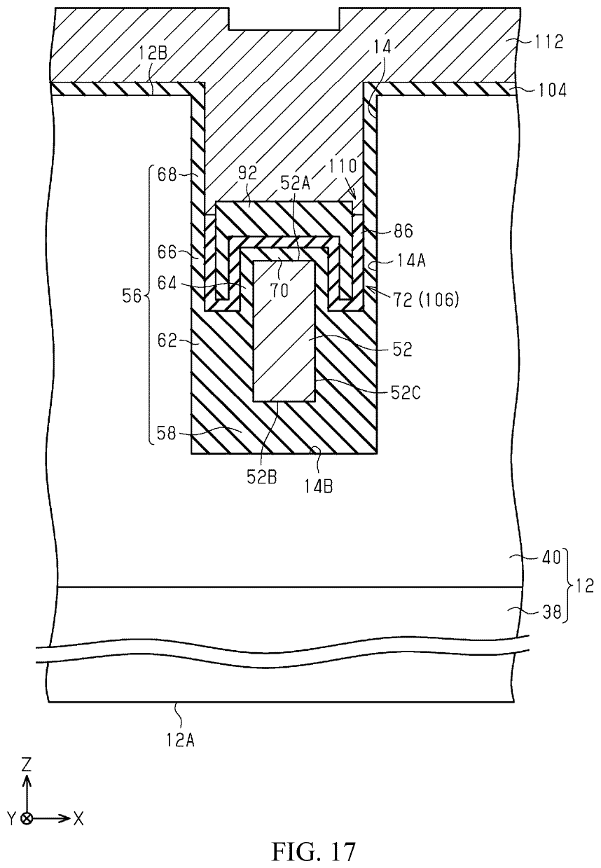

Although not shown in the drawings, the manufacturing method of the semiconductor device 10 includes a step of forming an oxide film. In the step above, by thermal oxidation, an oxide film is formed on each of the second SiO-based insulating layer 104 covering the side wall 14A of the gate trench 14 and the second surface 12B of the semiconductor layer 12, the third insulating layer 92, and an end surface of the protruding portion 86 exposed from the second insulating layer 72. The oxide film is, for example, a SiO₂ film. Next, by etching, for example, the oxide film on the second SiO-based insulating layer 104 and the third insulating layer 92 is removed. Accordingly, an oxide film 90 (referring to FIG. 4) formed on the end surface of the protruding portion 86 is formed. Moreover, after FIG. 17, for better illustration purposes, the oxide film 90 is not depicted.

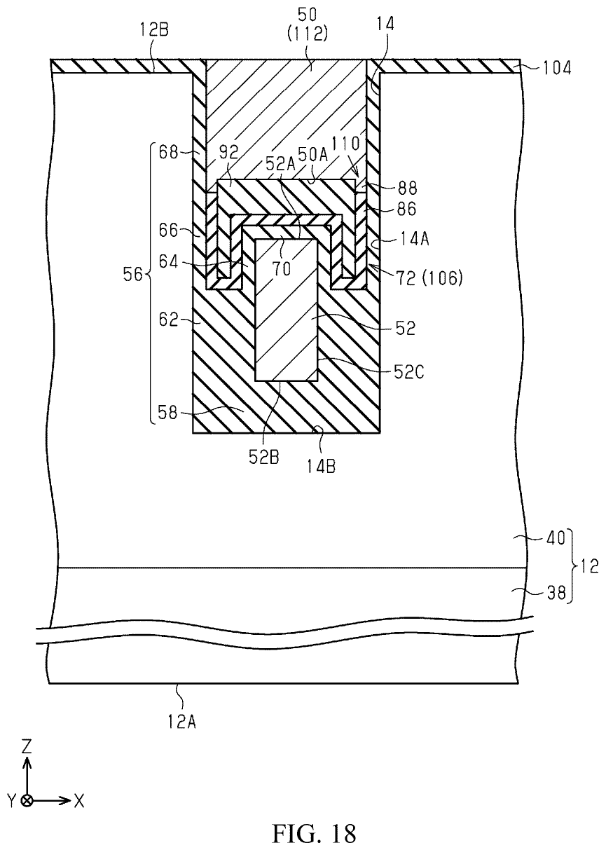

As shown in FIG. 17 and FIG. 18, the manufacturing method of the semiconductor device 10 includes forming the gate electrode 50 in the gate trench 14.

As shown in FIG. 17, the forming of the gate electrode 50 in the gate trench 14 includes forming a second conductive layer 112 on the third insulating layer 92 and on the second SiO-based insulating layer 104. A portion of the second conductive layer 112 is embedded in the recess space formed in the gate trench 14. A portion of the second conductive layer 112 can be formed on the second SiO-based insulating layer 104 covering the second surface 12B of the semiconductor layer 12. A portion of the second conductive layer 112 can be embedded in the recess 110. The second conductive layer 112 can be, for example, conductive polysilicon. The second conductive layer 112 can be formed by, for example, sputtering.

As shown in FIG. 18, the forming of the gate electrode 50 in the gate trench 14 includes removing a portion of the second conductive layer 112 by etching. In the step above, by etching the second conductive layer 112, the second SiO-based insulating layer 104 covering the second surface 12B of the semiconductor layer 12 is exposed. With the steps above, the gate electrode 50 is formed. The portion of the second conductive layer 112 embedded in the recess 110 can form the gate-side protrusion 88.

Thus, the gate electrode 50 can be formed to be closer to the second surface 12B of the semiconductor layer 12 than the second insulating layer 72. Accordingly, the second insulating layer 72 can be formed between the bottom surface 52B of the field plate electrode 52 and the bottom surface 50A of the gate electrode 50 along the Z direction. That is to say, the forming of the second insulating layer 72 includes forming between the bottom surface 52B of the field plate electrode 52 and the bottom surface 50A of the gate electrode 50 along the Z direction.

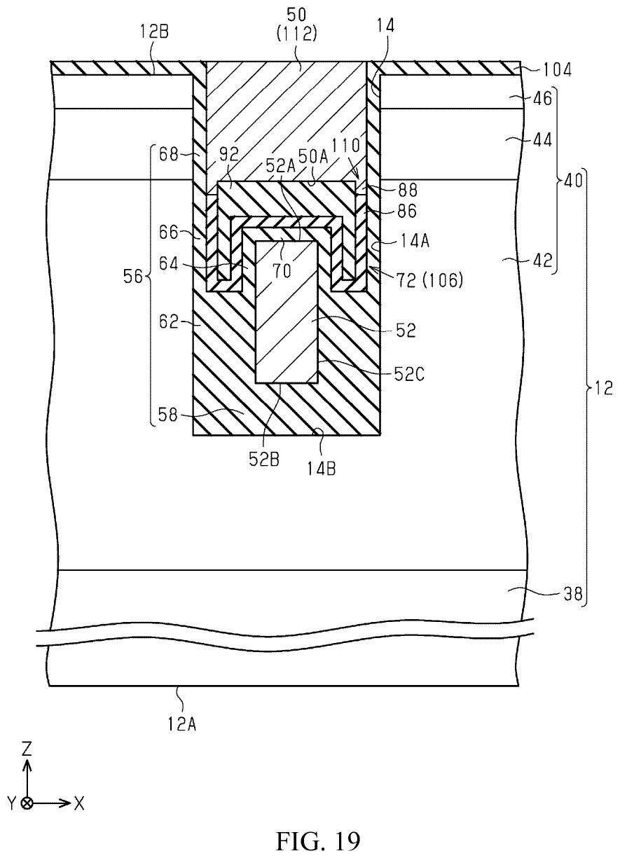

As shown in FIG. 19, the manufacturing method of the semiconductor device 10 includes forming the drift region 42, the body region 44 and the source region 46 in the epitaxial layer 40. In the step above, by ion implantation using a mask (omitted from the drawing), p-type impurities are implanted from an n-type Si layer, that is, a surface (the second surface 12B of the semiconductor layer 12) of the epitaxial layer 40, and then n-type impurities are implanted. Accordingly, the body region 44 can be formed on the drift region 42. The source region 46 can be formed on the body region 44. With the steps above, the semiconductor layer 12 is formed. That is to say, the forming of the semiconductor layer 12 includes forming the N-type drift region 42, forming the p-type body region 44 on the drift region 42, and forming the n-type source region 46 on the body region 44.

In this case, the second insulating layer 72 can be located at a position closer to the first surface 12A of the semiconductor layer 12 than the body region 44. That is to say, the second insulating layer 72 can be formed at a position adjacent to the drift region 42 in the first insulating layer 56. More specifically, the second insulating layer 72 can be formed at a position adjacent to the drift region 42 across from the first insulating layer 56 (the second side insulating portion 78) along the X direction.

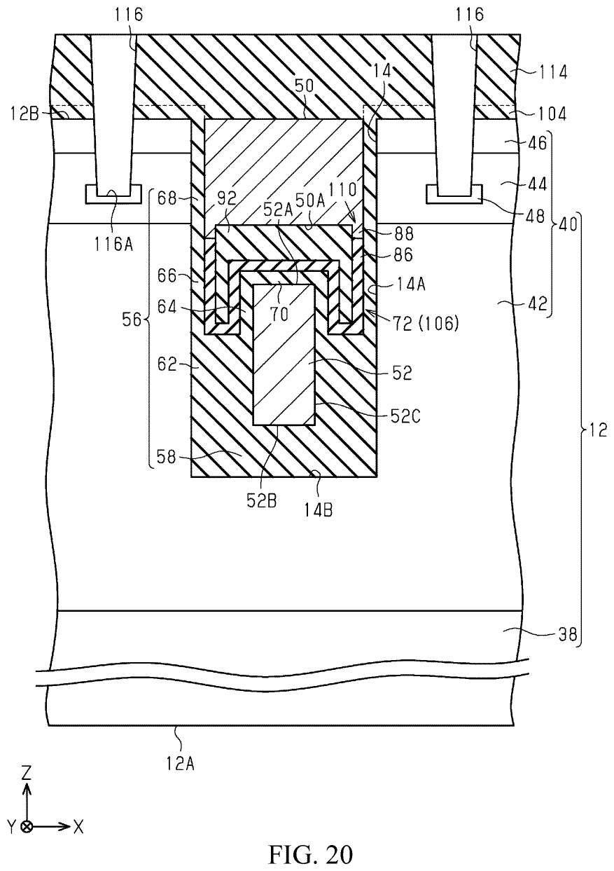

As shown in FIG. 20, the manufacturing method of the semiconductor device 10 includes forming a fourth SiO-based insulating layer 114 covering the second SiO-based insulating layer 104 and the gate electrode 50, and forming a contact trench 116 and the contact region 48.

The forming of the fourth SiO-based insulating layer 114 can form the fourth SiO-based insulating layer 114 in the recess space formed by the second SiO-based insulating layer 104 of the gate trench 14 and the gate electrode 50, and on the second SiO-based insulating layer 104 covering the second surface 12B of the semiconductor layer 12. The fourth SiO-based insulating layer 114 can be embedded in the recess space. In an example, the fourth SiO-based insulating layer 114 can be SiO₂ formed by CVD. Thus, the fourth SiO-based insulating layer 114 can be a SiO₂ film. The fourth SiO-based insulating layer 114 can be formed to have a greater thickness. In an example, the fourth SiO-based insulating layer 114 can be formed to have a thickness greater than that of the second insulating layer 72. With the steps above, the insulating layer 16 is formed.

The contact trench 116 can be formed by etching a portion of the fourth SiO-based insulating layer 114 and the second SiO-based insulating layer 104 on the second surface 12B of the semiconductor layer 12, and a portion of the semiconductor layer 12. Accordingly, the contact trench 116 opens up the second surface 12B of the semiconductor layer 12. Then, by implanting p-type impurities into a bottom wall 116A of the contact trench 116, the contact region 48 can be formed on the bottom wall 116A of the contact trench 116.

After the step shown in FIG. 20, with a metal layer (for example, W, Ti, TiN or any combination thereof) embedded in the contact trench 116, the wiring contact 34 shown in FIG. 3 can be formed. Meanwhile, the contacts 30, 32 and 36 shown in FIG. 1 can also be formed. Next, by forming the gate wiring 26 (referring to FIG. 1) and the source wiring 28 on the insulating layer 16 and forming the drain electrode 54 (referring to FIG. 2) on the first surface 12A of the semiconductor layer 12, the semiconductor device 10 can be obtained. Moreover, with the step above, the source region 46 can be set to the same potential as the field plate electrode 52.

The manufacturing method of the semiconductor device 10 including the multiple manufacturing steps sequentially performed is as described above. However, it should be understood that, some of the manufacturing steps can be performed in parallel or can be performed in a different order. Moreover, some of the manufacturing steps can be omitted, or processing different from that provided in the examples can be performed in any of the manufacturing steps.

### [Functions]

Functions of the semiconductor device 10 according to this embodiment are described below.

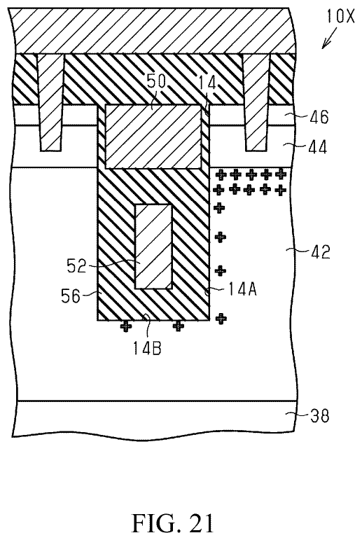

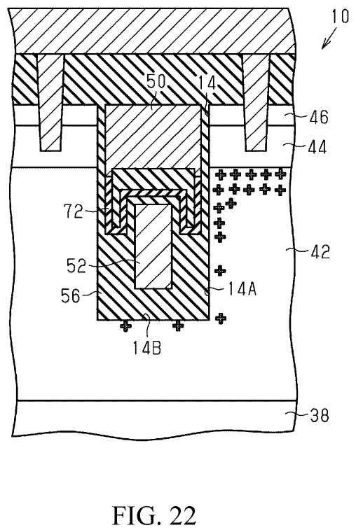

FIG. 21 shows a cross-section structure of one gate trench 14 and its periphery of a semiconductor device 10X of a comparison example. FIG. 22 shows a cross-section structure of one gate trench 14 and its periphery of the semiconductor device 10 of this embodiment. In FIG. 21 and FIG. 22, the symbol “+” denotes a donor.

As shown in FIG. 21, the semiconductor device 10X of the comparison example is a configuration from which the second insulating layer 72 (referring to FIG. 22) is omitted from the semiconductor device 10. That is to say, the first insulating layer 56, the field plate electrode 52 and the gate electrode 50 are embedded in the gate trench 14.

In the semiconductor device 10X of the comparison example, if a voltage is applied to the gate electrode 54, the donors in the drift region 42 directly below the body region 44 are not fully ionized. As a result, electric field concentration is generated in the drift region 42 directly below the body region 44, and so it is difficult to increase the withstand voltage of the semiconductor device 10X of the comparison example.

As shown in FIG. 22, in the semiconductor device 10 of this embodiment, the second insulating layer 72 having a dielectric constant greater than that of the first insulating layer 56 is disposed in the gate trench 14 and at a position adjacent to the drift region 42. Accordingly, a depletion layer is allowed to extend from the drift region 42 directly below the body region 44 along the Z direction, and so electric field concentration in the drift region 42 directly below the body region 44 can be alleviated. Thus, the withstand voltage of the semiconductor device 10 can be increased.

### [Effects]

The semiconductor device 10 of this embodiment achieves the following effects.

(1) A semiconductor device 10 includes: a semiconductor layer 12, having a first surface 12A and a second surface 12B opposite to the first surface 12A; a gate trench 14, formed on the second surface 12B of the semiconductor layer 12, having a side wall 14A and a bottom wall 14B and extending along a Y direction in a plan view; a field plate electrode 52, formed in the gate trench 14; a gate electrode 50, including a bottom surface 50A at least partially facing the field plate electrode 52 in the gate trench 14; and an insulating layer 16, separating the field plate electrode 52 and the gate electrode 50 from each other and covering the side wall 14A and the bottom wall 14B of the gate trench 14. The semiconductor layer 12 includes: an n-type drift region 42; a p-type body region 44 formed on the drift region 42; and an n-type source region 46, formed on the body region 44 and having same potential as the field plate electrode 52. The insulating layer 16 includes: a first insulating layer 56, covering the side wall 14A and the bottom wall 14B and covering the field plate electrode 52; and a second insulating layer 72, formed on the first insulating layer 56 and at a position adjacent to the drift region 42, wherein the second insulating layer 72 has a dielectric constant greater than a dielectric constant of the first insulating layer 56. The field plate electrode 52 includes a bottom surface 52B facing the bottom wall 14B of the gate trench 14. The second insulating layer 72 is disposed between the bottom surface 52B of the field plate electrode 52 and the bottom surface 50A of the gate electrode 50 along a Z direction.

According to the configuration above, since the second insulating layer 72 having a dielectric constant higher than that of the first insulating layer 56 is formed at a position adjacent to the drift region 42, electric field concentration of a region directly below the body region 44 in the drift region 42 can be alleviated. Thus, the withstand voltage of the semiconductor device 10 can be increased.

Moreover, because the second insulating layer 72 is not formed between the gate electrode 50 and the source region 46, a further increase in capacitance (gate-source capacitance) between the gate electrode 50 and the source region 46 can be suppressed. Thus, influences on switching characteristics of the semiconductor device 10 can be suppressed.

(2) The second insulating layer 72 includes an opposing portion 74 disposed between the gate electrode 50 and the field plate electrode 52 along the Z direction.

According to the configuration above, the opposing portion 74 of the second insulating layer 72 forms a portion of a dielectric film of a capacitor formed by the gate electrode 50 and the field plate electrode 52. Thus, by adjusting a dielectric constant of the capacitor by the opposing portion 74, a margin for automatically turning on the semiconductor device 10 can be ensured.

(3) The second insulating layer 72 includes a side opposing portion 76 disposed opposite to a side surface 52C of the field plate electrode 52.

According to the configuration above, with the side opposing portion 76, a depletion layer can be easily formed in the drift region 42 adjacent to the side opposing portion 76. Thus, electric field concentration of the region directly below the body region 44 in the drift region 42 can be alleviated.

(4) The second insulating layer 72 includes a protruding portion 86 formed continuously from the side opposing portion 76 and protruding from the opposing portion 74 toward the gate electrode 50.

According to the configuration above, with the protruding portion 86, a depletion layer can be easily formed in the drift region 42 adjacent to the protruding portion 86. Thus, electric field concentration of the region directly below the body region 44 in the drift region 42 can be alleviated

(5) A portion of the gate electrode 50 facing the protruding portion 86 of the second insulating layer 72 along the Z direction includes a gate-side protrusion 88 protruding from the bottom surface 50A of the gate electrode 50 toward the protruding portion 86. An oxide film 90 is interposed between the protruding portion 86 along the Z direction and the gate-side protrusion 88.

According to the configuration above, with the oxide film 90, a contact between the second insulating layer 72 having a higher dielectric constant with the gate electrode 50 can be suppressed. Thus, influences on a withstand voltage between the gate electrode 50 and the field plate electrode 52 can be suppressed.

(6) The insulating layer 16 includes a third insulating layer 92 formed between the second insulating layer 72 and the gate electrode 50 along the Z direction. A dielectric constant of the third insulating layer 92 is less than a dielectric constant of the second insulating layer 72.

According to the configuration above, with the third insulating layer 92, the contact between the second insulating layer 72 having a higher dielectric constant with the gate electrode 50 can be suppressed. Thus, influences on a withstand voltage between the gate electrode 50 and the field plate electrode 52 can be suppressed.

(7) A maximum dimension WG of the gate electrode 50 along the X direction is greater than or equal to a maximum dimension WD of the second insulating layer 72 along the X direction.

According to the configuration above, by increasing the dimension of the gate electrode 50 along the X direction, that is, the width, resistance of the gate electrode 50 can be reduced.

(8) A method of forming a semiconductor device 10 comprises: forming a semiconductor layer 12 having a first surface 12A and a second surface 12B opposite to the first surface 12A; forming a gate trench 14 on the second surface 12B of the semiconductor layer 12, wherein the gate trench 14 has a side wall 14A and a bottom wall 14B and extends along a Y direction in a plan view; forming a field plate electrode 52 in the gate trench 14; forming a gate electrode 50 in the gate trench 14, wherein the gate electrode 50 includes a bottom surface 50A at least partially facing the field plate electrode 52; and forming an insulating layer 16 to separate the field plate electrode 52 from the gate electrode 50 and cover the side wall 14A and the bottom wall 14B of the gate trench 14. The forming of the semiconductor layer 12 includes: forming an N-type drift region 42; forming a p-type body region 44 on the drift region 42; and forming an n-type source region 46 on the body region 44, wherein the source region 46 has same potential as the field plate electrode 52. The forming of the insulating layer 16 includes: forming a first insulating layer 56 that covers the side wall 14A and the bottom wall 14B of the gate trench 14 and covers the field plate electrode 52; and forming a second insulating layer 72 on the first insulating layer 56 and at a position adjacent to the drift region 42, wherein the second insulating layer 72 has a dielectric constant greater than a dielectric constant of the first insulating layer 56. The field plate electrode 52 includes a bottom surface 52B facing the bottom wall 14B of the gate trench 14. The forming of the second insulating layer 72 includes forming the second insulating layer 72 between the bottom surface 52B of the field plate electrode 52 and the bottom surface 50A of the gate electrode 50 along a Z direction.

According to the configuration above, since the second insulating layer 72 having a dielectric constant higher than that of the first insulating layer 56 is formed at a position adjacent to the drift region 42, electric field concentration of a region directly below the body region 44 in the drift region 42 can be alleviated. Thus, the withstand voltage of the semiconductor device 10 can be increased.

Moreover, because the second insulating layer 72 is not formed between the gate electrode 50 and the source region 46, a further increase in capacitance (gate-source capacitance) between the gate electrode 50 and the source region 46 can be suppressed. Thus, influences on switching characteristics of the semiconductor device 10 can be suppressed.

### <Variation Examples>

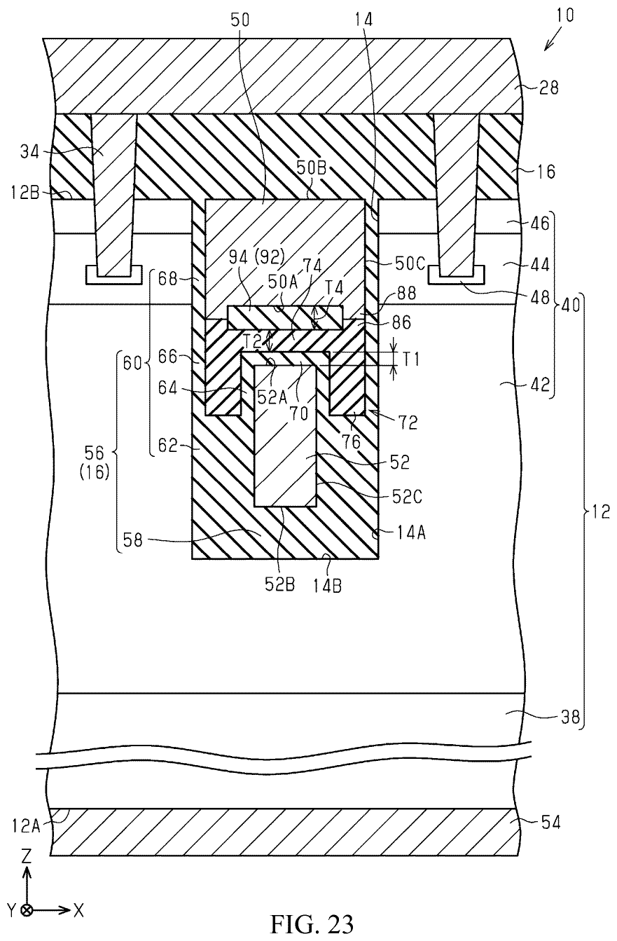

The embodiments can be modified as follows and be accordingly implemented. Given that no technical contradiction is caused, the variation examples may be used in combination.
The configuration of the side opposing portion 76 of the second insulating layer 72 can be modified as desired. In an example, as shown in FIG. 23, by forming the second insulating layer 72 having a greater thickness, a recess 84 (referring to FIG. 3) is omitted from the second insulating layer 72. That is to say, in the sectional view of FIG. 23, the side opposing portion 76 is formed to having a linear shape extending along the side wall 14A of the gate trench 14 in substitution for a recessed shape formed by the first side opposing portion 78, the second side opposing portion 80 and the connection portion 82 (referring to FIG. 3 for all of the above). In this case, the embedded portion 96 (referring to FIG. 3) is omitted from the third insulating layer 92. Moreover, according to the thickness of the second insulating layer 72, a width (a dimension along the X direction) of the protruding portion 86 is increased, and so a width (a dimension along the X direction) of the gate-side protrusion 88 of the gate electrode 50 is also increased.

Moreover, in the example shown in FIG. 23, the thickness T2 of the second insulating layer 72 is greater than the thickness T1 of the opposing insulating layer 70. The thickness T2 of the second insulating layer 72 is equal to the thickness T4 of the third insulating layer 92. Moreover, if a difference between the thickness T2 of the second insulating layer 72 and the thickness T4 of the third insulating layer 92 is within 10% of the thickness T2 of the second insulating layer 72, it can be said that the thickness T2 of second insulating layer 72 is equal to the thickness T4 of the third insulating layer 92.

In addition, the thickness T2 of the second insulating layer 72 can be modified as desired. In an example, the thickness T2 of the second insulating layer 72 can be less than the thickness T4 of the third insulating layer 92. In another example, the thickness T2 of the second insulating layer 72 can be greater than the thickness T4 of the third insulating layer 92.
The protruding portion 86 of the second insulating layer 72 can be in contact with the gate-side protrusion 88 of the gate electrode 50. That is to say, the oxide film 90 between the protruding portion 86 and the gate-side protrusion 88 along the Z direction can also be omitted.
A relationship between the maximum dimension WD of the second insulating layer 72 along the X direction and the maximum dimension WG of the gate electrode 50 along the X direction can be modified as desired. In an example, the maximum dimension WD of the second insulating layer 72 along the X direction can also be less than the maximum dimension WG of the gate electrode 50 along the X direction. In another example, the maximum dimension WD of the second insulating layer 72 along the X direction can also be greater than the maximum dimension WG of the gate electrode 50 along the X direction.
The position of the connection portion 82 of the second insulating layer 72 along the Z direction can be modified as desired. In an example, the connection portion 82 can also be located between a center of the field plate electrode 52 along the Z direction and the bottom surface 52B along the Z direction.
The protruding portion 86 can also be omitted from the second insulating layer 72.
The side opposing portion 76 can also be omitted from the second insulating layer 72. In this case, the second insulating layer 72 is disposed between the opposing surface 52A of the field plate electrode 52 and the bottom surface 50A of the gate electrode 50 along the Z direction.
The dielectric constant of the second insulating layer 72 can be modified as desired. In an example, the dielectric constant of the second insulating layer 72 only has to be different from the dielectric constant of the first insulating layer 56. That is to say, the dielectric constant of the second insulating layer 72 can also be less than the dielectric constant of the first insulating layer 56. In another example, the dielectric constant of the second insulating layer 72 can also be different from the dielectric constant of the third insulating layer 92. That is to say, the dielectric constant of the second insulating layer 72 can also be less than the dielectric constant of the third insulating layer 92.
The opposing insulating portion 70 can also be omitted from the first insulating layer 56. In this case, the opposing portion 74 of the second insulating layer 72 can also be formed to be in contact with the opposing surface 52A of the field plate electrode 52.
At least one of the first interposing portion 64 and the second interposing portion 66 can also be omitted from the first insulating layer 56. When the first interposing portion 64 is omitted, the side opposing portion 76 of the second insulating layer 72 can also be formed to be in contact with the side surface 52C of the field plate electrode 52. When the second interposing portion 66 is omitted, the side opposing portion 76 of the second insulating layer 72 can also be formed to be in contact with the side wall 14A of the gate trench 14.
The dielectric constant of the third insulating layer 92 can be modified as desired. In an example, the dielectric constant of the third insulating layer 92 can also be different from the dielectric constant of the first insulating layer 56. That is to say, the dielectric constant of the third insulating layer 92 can also be less than the dielectric constant of the first insulating layer 56. Moreover, the dielectric constant of the third insulating layer 92 can be greater than the dielectric constant of the first insulating layer 56.
The oxide film 90 between the gate-side protrusion 88 of the gate electrode 50 and the protruding portion 86 of the second insulating layer 72 can also be omitted. In this case, the gate-side protrusion 88 is in contact with the protruding portion 86.
The configuration of the gate electrode 50 can be modified as desired. In an example, the gate-side protrusion 88 can also be omitted from the gate electrode 50.
The peripheral trench 18 can also be disposed in two linear trenches on both sides of multiple gate trenches 14, instead of being disposed in a rectangular trench.
Alternatively, a structure in which conductivity types of individual regions in the semiconductor layer 12 are inverted can also be adopted. That is to say, a p-type region can be set as an n-type region, and an n-type region can be set as a p-type region.
In the manufacturing method of the semiconductor device 10, an insulating layer formed on the second SiO-based insulating layer 104 and the gate electrode 50 is not limited to the fourth SiO-based insulating layer 114. In an example, the insulating layer can be SiN, SiO₂ or a combination thereof.

One or more examples recited in the present application can be combined within scopes that are non-technically contradictory.

In the present application, the expression “at least one of A and B” should be understood as “only A, or only B, or both of A and B”.

The terms such as “on” used in the present disclosure also includes meanings of “over” and “above”, unless otherwise specified in the context. Thus, the expression “a first element disposed on a second element” can refer to that the first element is in contact with the second element and directly arranged on the second element in some embodiments, or can refer to that the first element is not in contact with the second element and is arranged over or above the second element in other embodiments. That is to say, the expression “on/over/above” does not eliminate a structure in which another element is formed between the first element and the second element.

The Z-direction used in the present disclosure is not necessarily a vertical direction, and is not necessarily completely consistent with the vertical direction. Thus, various structures associated with the present disclosure do not limit “up/top” and “down/bottom” of the Z direction provided in the description to be “up” and “down” of the vertical direction. For example, the X-direction can be the vertical direction, or the Y-direction can be the vertical direction.

### Note

The technical ideas that can be understood from the above embodiment and each modification example will be described below. Note that the reference numerals of the constituent elements of the embodiment corresponding to the constituent elements described in each supplementary note are shown in parentheses. The symbols are shown as examples to aid understanding, and the components described in each appendix should not be limited to the components indicated by the symbols.

### [Note A1]

A semiconductor device (10), comprising:
a semiconductor layer (12), having a first surface (12A) and a second surface (12B) opposite to the first surface (12A);
a trench (14), formed on the second surface (12B) of the semiconductor layer (12), having a side wall (14A) and a bottom wall (14B) and extending along a first direction (Y direction) when viewed from a thickness direction (Z direction) of the semiconductor layer (12);
a field plate electrode (52), formed in the trench (14);
a gate electrode (50), including a bottom surface (50B) at least partially facing the field plate electrode (52) in the trench (14); and
an insulating layer (16), separating the field plate electrode (52) and the gate electrode (50) from each other and covering the side wall (14A) and the bottom wall (14B) of the trench (14), wherein
the semiconductor layer (12) includes:
   a drift region (42) of a first conductivity type (n type);
   a body region (44) of a second conductivity type (p type) on the drift region (42); and
   a source region (46) of the first conductivity type (n type), formed on the body region (44) and having same potential as the field plate electrode (52),
the insulating layer (16) includes:
   a first insulating layer (56), covering the side wall (14A) and the bottom wall (14B) of the trench (14) and covering the field plate electrode (52); and
   a second insulating layer (72), formed on the first insulating layer (56) and at a position adjacent to the drift region (42), wherein the second insulating layer (72) has a dielectric constant greater than a dielectric constant of the first insulating layer (56),
the field plate electrode (52) includes a bottom surface (50B) facing the bottom wall (14B) of the trench (14), and
the second insulating layer (72) is disposed between the bottom surface (50B) of the field plate electrode (52) and the bottom surface (50B) of the gate electrode (50) along a depth direction (Z direction) of the trench (14).

### [Note A2]

The semiconductor device of Note A1, wherein the second insulating layer (72) includes an opposing portion (74) disposed between the gate electrode (50) and the field plate electrode (52) along the depth direction (Z direction).

### [Note A3]

The semiconductor device of Note A2, wherein
the field plate electrode (52) includes an opposing surface (52A) facing the gate electrode (50) along the depth direction (Z direction),
the first insulating layer (56) includes an opposing insulating portion (70) covering the opposing surface (52A), and
the opposing portion (74) of the second insulating layer (72) is formed on the opposing insulating portion (70).

### [Note A4]

The semiconductor device of Note A2 or A3, wherein
the second insulating layer (72) includes a side opposing portion (76) disposed opposite to a side surface (52C) of the field plate electrode (52).

### [Note A5]

The semiconductor device of Note A4, wherein
a direction perpendicular to the first direction (Y direction) when viewed from the thickness direction (Z direction) of the semiconductor layer (12) is set as a second direction (X direction),
the side opposing portion (76) includes:
   a first side opposing portion (78), extending from the opposing portion (74) toward the bottom wall (14B) of the trench (14);
   a second side opposing portion (80), facing the first side opposing portion (78) along the second direction (X direction) and spaced apart from the first side opposing portion (78) toward the side wall (14A) of the trench (14); and
   a connection portion (82), connecting an end of the first side opposing portion (78) closer to the bottom wall (14B) of the trench (14) and the second side opposing portion (80).

### [Note A6]

The semiconductor device of Note A5, wherein the connection portion (82) is disposed closer to the gate electrode (50) than a center of the field plate electrode (52) along the depth direction (Z direction).

### [Note A7]

The semiconductor device of any one of Notes A4 to A6, wherein the second insulating layer (72) includes a protruding portion (86) formed continuously from the side opposing portion (76) and protruding from the opposing portion (74) toward the gate electrode (50).

### [Note A8]

The semiconductor device of Note A7, wherein
the gate electrode (50) faces the protruding portion (86) along the depth direction (Z direction),
a portion of the gate electrode (50) facing the protruding portion (86) along the depth direction (Z direction) includes a gate-side protrusion (88) protruding from the bottom surface (50B) of the gate electrode (50) toward the protruding portion (86).

### [Note A9]

The semiconductor device of Note A8, wherein an oxide film (90) is interposed between the protruding portion (86) along the depth direction (Z direction) and the gate-side protrusion (88).

### [Note A10]

The semiconductor device of any one of Notes A1 to A9, wherein
the insulating layer (16) includes a third insulating layer (92) formed between the second insulating layer (72) and the gate electrode (50) along the depth direction (Z direction), and
the third insulating layer (92) has a dielectric constant less than the dielectric constant of the second insulating layer (72).

### [Note A11]

The semiconductor device of Note A10, wherein the dielectric constant of the third insulating layer (92) is same as the dielectric constant of the first insulating layer (56).

### [Note A12]

The semiconductor device of any one of Notes A2 to A9, wherein
the insulating layer (16) includes a third insulating layer (92) formed between the second insulating layer (72) and the gate electrode (50) along the depth direction (Z direction), and
a thickness (T4) of a portion of the third insulating layer (92) sandwiched between the bottom surface (50B) of the gate electrode (50) and the opposing portion (74) of the second insulating layer (72) is greater than a thickness (T2) of the opposing portion (74).

### [Note A13]

The semiconductor device of Note A3, wherein
the insulating layer (16) includes a third insulating layer (92) formed between the second insulating layer (72) and the gate electrode (50) along the depth direction (Z direction), and
a thickness (T4) of a portion of the third insulating layer (92) sandwiched between the bottom surface (50B) of the gate electrode (50) and the opposing portion (74) of the second insulating layer (72) is greater than a thickness (T1) of the opposing insulating portion (70) of the first insulating layer (56).

### [Note A14]

The semiconductor device of Note A5 or A6, wherein
the insulating layer (16) includes a third insulating layer (92) formed between the second insulating layer (72) and the gate electrode (50) along the depth direction (Z direction), and
the third insulating layer (92) is into a recess (84) formed by the first side opposing portion (78), the connection portion (82) and the second side opposing portion (80).

### [Note A15]

The semiconductor device of Note A5 or A6, wherein the first insulating layer (56) includes:
a first intermediate portion (64), inserted between the field plate electrode (52) and the first side opposing portion (78) along the second direction (X direction); and
a second intermediate portion (66), inserted between the second side opposing portion (80) and the side wall (14A) of the trench (14) along the second direction (X direction);

### [Note A16]

The semiconductor device of any one of Notes A1 to A15, wherein
a direction perpendicular to the first direction (Y direction) when viewed from the thickness direction (Z direction) of the semiconductor layer (12) is set as a second direction (X direction), and
a maximum dimension (WG) of the gate electrode (50) along the second direction (X direction) is greater than or equal to a maximum dimension (WD) of the second insulating layer (72) along the second direction (X direction).

### [Note A17]

The semiconductor device of any one of Notes A1 to A16, wherein
the first insulating layer (56) is a SiO₂ film, and
the second insulating layer (72) is any one of a SiN film, a SiON film and a HfO₂ film.

### [Note A18]

The semiconductor device of Note A17, wherein
the insulating layer (16) includes a third insulating layer (92) formed between the second insulating layer (72) and the gate electrode (50) along the depth direction (Z direction), and
the third insulating layer (92) is a SiO₂ film.

### [Note A19]

A method of forming a semiconductor device (10), comprising:
forming a semiconductor layer (12) having a first surface (12A) and a second surface (12B) opposite to the first surface (12A);
forming a trench (14) on the second surface (12B) of the semiconductor layer (12), wherein the trench (14) has a side wall (14A) and a bottom wall (14B) and extends along a first direction (Y direction) when viewed from a thickness direction (Z direction) of the semiconductor layer (12);
forming a field plate electrode (52) in the trench (14);
forming a gate electrode (50) in the trench (14), wherein the gate electrode (50) includes a bottom surface (50B) at least partially facing the field plate electrode (52); and
forming an insulating layer (16) to separate the field plate electrode (52) from the gate electrode (50) and cover the side wall (14A) and the bottom wall (14B) of the trench (14), wherein
the forming of the semiconductor layer (12) includes:
   forming a drift region (42) of a first conductivity type (n type);
   forming a body region (44) of a second conductivity type (p type) on the drift region (42); and
   forming a source region (46) of the first conductivity type (n type) on the body region (44), wherein the source region (46) has same potential as the field plate electrode (52);
the forming of the insulating layer (16) includes:
   forming a first insulating layer (56) that covers the side wall (14A) and the bottom wall (14B) of the trench (14) and covers the field plate electrode (52); and
   forming a second insulating layer (72) on the first insulating layer (56) and at a position adjacent to the drift region (42), wherein the second insulating layer (72) has a dielectric constant greater than a dielectric constant of the first insulating layer (56),
the field plate electrode (52) includes a bottom surface (50B) facing the bottom wall (14B) of the trench (14), and
the forming of the second insulating layer (72) includes forming the second insulating layer (72) between the bottom surface (50B) of the field plate electrode (52) and the bottom surface (50B) of the gate electrode (50) along a depth direction (Z direction) of the trench (14).

### [Note A20]

The method of forming the semiconductor device of Note A19, wherein
the forming of the insulating layer (16) includes forming a third insulating layer (92) between the first insulating layer (56) and the bottom surface (50B) of the gate electrode (50), and
the third insulating layer (92) has a dielectric constant less than the dielectric constant of the second insulating layer (72).

### [Note B1]

A semiconductor device (10), comprising:
a semiconductor layer (12), having a first surface (12A) and a second surface (12B) opposite to the first surface (12A);
a trench (14), formed on the second surface (12B) of the semiconductor layer (12), having a side wall (14A) and a bottom wall (14B) and extending along a first direction (Y direction) when viewed from a thickness direction (Z direction) of the semiconductor layer (12);
a field plate electrode (52), formed in the trench (14);
a gate electrode (50), including a bottom surface (50B) at least partially facing the field plate electrode (52) in the trench (14); and
an insulating layer (16), separating the field plate electrode (52) and the gate electrode (50) from each other and covering the side wall (14A) and the bottom wall (14B) of the trench (14), wherein
the semiconductor layer (12) includes:
   a drift region (42) of a first conductivity type (n type);
   a body region (44) of a second conductivity type (p type) on the drift region (42); and
   a source region (46) of the first conductivity type (n type), formed on the body region (44) and having same potential as the field plate electrode (52),
the insulating layer (16) includes:
   a first insulating layer (56), covering the side wall (14A) and the bottom wall (14B) of the trench (14) and covering the field plate electrode (52); and
   a second insulating layer (72), formed on the first insulating layer (56), wherein the second insulating layer (72) has a dielectric constant different from a dielectric constant of the first insulating layer (56), and
   the first insulating layer (56) and the second insulating layer (72) are disposed between the field plate electrode (52) and the gate electrode (50) along a depth direction (Z direction) of the trench (14).

### [Problems to be Solved by Note B1]

When a semiconductor device performs a switching operation, there is a concern that a voltage between the drain and the source of the semiconductor device rises sharply in an off state due to a capacitance between the gate and the drain of the semiconductor device and a capacitance between the gate and the source. The ratio of capacitance to gate electrode produces voltage. When the voltage exceeds the gate threshold voltage, the semiconductor device switches on incorrectly, resulting in a so-called automatic turn-on.

### [Effects]

According to the above configuration, the capacitance of the capacitor configured by the first insulating layer and the second insulating layer between the field plate electrode and the gate electrode can be adjusted by changing relative dielectric constants of the first insulating layer and the second insulating layer, which have different dielectric constants. Thus, for example, by increasing the gate-source voltage, a margin for automatic turn-on can be ensured. As a result, the occurrence of automatic turn-on can be suppressed.

### [Note B2]

The semiconductor device of Note B1, wherein
the field plate electrode (52) includes an opposing surface (52A) facing the gate electrode (50) along the depth direction (Z direction),
the first insulating layer (56) includes an opposing insulating portion (70) covering the opposing surface (52A), and
the second insulating layer (72) is formed on the opposing insulating portion (70).

### [Note B3]

The semiconductor device of Note B2, wherein
the insulating layer (16) includes a third insulating layer (92) formed between the second insulating layer (72) and the gate electrode (50) along the depth direction (Z direction),
the third insulating layer (92) has a dielectric constant different from the dielectric constant of the second insulating layer (72).

### [Note B4]

The semiconductor device of Note B3, wherein
the second insulating layer (72) includes an opposing portion (74) disposed between the gate electrode (50) and the field plate electrode (52) along the depth direction (Z direction), and
a thickness (T4) of a portion of the third insulating layer (92) sandwiched between the bottom surface (50B) of the gate electrode (50) and the opposing portion (74) of the second insulating layer (72) is greater than a thickness (T2) of the opposing portion (74).

### [Note B5]

The semiconductor device of Note B4, wherein
the thickness (T4) of the portion of the third insulating layer (92) sandwiched between the bottom surface (50B) of the gate electrode (50) and the opposing portion (74) of the second insulating layer (72) is greater than a thickness (T1) of the opposing insulating portion (70) of the first insulating layer (56).

### [Note B6]

The semiconductor device of any one of Note B1 to B5, wherein
The dielectric constant of the second insulating layer (72) is less than the dielectric constant of the first insulating layer (56).

### [Note B7]

The semiconductor device of any one of Note B3 to B5, wherein
The dielectric constant of the second insulating layer (72) is less than the dielectric constant of the third insulating layer (92).

### [Note B8]

The semiconductor device of any one of Note B3 to B5, wherein
The dielectric constant of the third insulating layer (92) is substantially equal to the dielectric constant of the first insulating layer (56).

The above description is merely illustrative. Those skilled in the art will recognize that many more possible combinations and permutations are possible beyond those listed for the purpose of describing the techniques of the present disclosure. The present disclosure is intended to cover all alternatives, variations, and modifications falling within the scope of this disclosure, including the claims.

1. A semiconductor device, comprising:
a semiconductor layer, having a first surface and a second surface opposite to the first surface;
a trench, formed on the second surface of the semiconductor layer, having a side wall and a bottom wall and extending along a first direction when viewed from a thickness direction of the semiconductor layer;
a field plate electrode, formed in the trench;
a gate electrode, including a bottom surface at least partially facing the field plate electrode in the trench; and
an insulating layer, separating the field plate electrode and the gate electrode from each other and covering the side wall and the bottom wall of the trench, wherein
the semiconductor layer includes:
a drift region of a first conductivity type;
a body region of a second conductivity type on the drift region; and
a source region of the first conductivity type, formed on the body region and having same potential as the field plate electrode,
the insulating layer includes:
a first insulating layer, covering the side wall and the bottom wall of the trench and covering the field plate electrode; and
a second insulating layer, formed on the first insulating layer and at a position adjacent to the drift region, wherein the second insulating layer has a dielectric constant greater than a dielectric constant of the first insulating layer,
the field plate electrode includes a bottom surface facing the bottom wall of the trench, and
the second insulating layer is disposed between the bottom surface of the field plate electrode and the bottom surface of the gate electrode along a depth direction of the trench.

2. The semiconductor device of claim 1, wherein the second insulating layer includes an opposing portion disposed between the gate electrode and the field plate electrode along the depth direction.

3. The semiconductor device of claim 2, wherein
the field plate electrode includes an opposing surface facing the gate electrode along the depth direction,
the first insulating layer includes an opposing insulating portion covering the opposing surface, and
the opposing portion of the second insulating layer is formed on the opposing insulating portion.

4. The semiconductor device of claim 2, wherein
the second insulating layer includes a side opposing portion disposed opposite to a side surface of the field plate electrode.

5. The semiconductor device of claim 4, wherein
a direction perpendicular to the first direction when viewed from the thickness direction of the semiconductor layer is set as a second direction,
the side opposing portion includes:
a first side opposing portion, extending from the opposing portion toward the bottom wall of the trench;
a second side opposing portion, facing the first side opposing portion along the second direction and spaced apart from the first side opposing portion toward the side wall of the trench; and
a connection portion, connecting an end of the first side opposing portion closer to the bottom wall of the trench and the second side opposing portion.

6. The semiconductor device of claim 5, wherein the connection portion is disposed closer to the gate electrode than a center of the field plate electrode along the depth direction.

7. The semiconductor device of claim 4, wherein the second insulating layer includes a protruding portion formed continuously from the side opposing portion and protruding from the opposing portion toward the gate electrode.

8. The semiconductor device of claim 7, wherein
the gate electrode faces the protruding portion along the depth direction,
a portion of the gate electrode facing the protruding portion along the depth direction includes a gate-side protrusion protruding from the bottom surface of the gate electrode toward the protruding portion.

9. The semiconductor device of claim 8, wherein an oxide film is interposed between the protruding portion along the depth direction and the gate-side protrusion.

10. The semiconductor device of claim 1, wherein
the insulating layer includes a third insulating layer formed between the second insulating layer and the gate electrode along the depth direction, and
the third insulating layer has a dielectric constant less than the dielectric constant of the second insulating layer.

11. The semiconductor device of claim 10, wherein the dielectric constant of the third insulating layer is same as the dielectric constant of the first insulating layer.

12. The semiconductor device of claim 2, wherein
the insulating layer includes a third insulating layer formed between the second insulating layer and the gate electrode along the depth direction, and
a thickness of a portion of the third insulating layer sandwiched between the bottom surface of the gate electrode and the opposing portion of the second insulating layer is greater than a thickness of the opposing portion.

13. The semiconductor device of claim 3, wherein
the insulating layer includes a third insulating layer formed between the second insulating layer and the gate electrode along the depth direction, and
a thickness of a portion of the third insulating layer sandwiched between the bottom surface of the gate electrode and the opposing portion of the second insulating layer is greater than a thickness of the opposing insulating portion of the first insulating layer.

14. The semiconductor device of claim 5, wherein
the insulating layer includes a third insulating layer formed between the second insulating layer and the gate electrode along the depth direction, and
the third insulating layer is into a recess formed by the first side opposing portion, the connection portion and the second side opposing portion.

15. The semiconductor device of claim 5, wherein the first insulating layer includes:
a first intermediate portion, inserted between the field plate electrode and the first side opposing portion along the second direction; and
a second intermediate portion, inserted between the second side opposing portion and the side wall of the trench along the second direction.

16. The semiconductor device of claim 1, wherein
a direction perpendicular to the first direction when viewed from the thickness direction of the semiconductor layer is set as a second direction, and
a maximum dimension of the gate electrode along the second direction is greater than or equal to a maximum dimension of the second insulating layer along the second direction.

17. The semiconductor device of claim 1, wherein
the first insulating layer is a SiO₂ film, and
the second insulating layer is any one of a SiN film, a SiON film and a HfO₂ film.

18. The semiconductor device of claim 17, wherein
the insulating layer includes a third insulating layer formed between the second insulating layer and the gate electrode along the depth direction, and
the third insulating layer is a SiO₂ film.

19. A method of forming a semiconductor device, comprising:
forming a semiconductor layer having a first surface and a second surface opposite to the first surface;
forming a trench on the second surface of the semiconductor layer, wherein the trench has a side wall and a bottom wall and extends along a first direction when viewed from a thickness direction of the semiconductor layer;
forming a field plate electrode in the trench;
forming a gate electrode in the trench, wherein the gate electrode includes a bottom surface at least partially facing the field plate electrode; and
forming an insulating layer to separate the field plate electrode from the gate electrode and cover the side wall and the bottom wall of the trench, wherein
the forming of the semiconductor layer includes:
forming a drift region of a first conductivity type;
forming a body region of a second conductivity type on the drift region; and
forming a source region of the first conductivity type on the body region, wherein the source region has same potential as the field plate electrode;
the forming of the insulating layer includes:
forming a first insulating layer that covers the side wall and the bottom wall of the trench and covers the field plate electrode; and
forming a second insulating layer on the first insulating layer and at a position adjacent to the drift region, wherein the second insulating layer has a dielectric constant greater than a dielectric constant of the first insulating layer,
the field plate electrode includes a bottom surface facing the bottom wall of the trench, and
the forming of the second insulating layer includes forming the second insulating layer between the bottom surface of the field plate electrode and the bottom surface of the gate electrode along a depth direction of the trench.

20. The method of forming the semiconductor device of claim 19, wherein
the forming of the insulating layer includes forming a third insulating layer between the first insulating layer and the bottom surface of the gate electrode, and
the third insulating layer has a dielectric constant less than the dielectric constant of the second insulating layer.
